(19) United States
(12) Patent Application Publication
(10) Pub. No.: US 2025/0126790 A1
(43) Pub. Date: Apr. 17, 2025

(54) NON-VOLATILE MEMORY DEVICE AND ELECTRONIC SYSTEM INCLUDING THE SAME

(71) Applicant: SAMSUNG ELECTRONICS CO., LTD., Suwon-si (KR)

(72) Inventors: Minyong Lee, Suwon-si (KR); Jiyoung Kim, Suwon-si (KR); Sehoon Lee, Suwon-si (KR); Junhyoung Kim, Suwon-si (KR); Sukkang Sung, Suwon-si (KR)

(21) Appl. No.: 18/756,161

(22) Filed: Jun. 27, 2024

(30) Foreign Application Priority Data
Oct. 11, 2023 (KR) 10-2023-0135450

(51) Int. Cl. H10B 43/27; H10B 41/10; H10B 41/27; H10B 41/41; H10B 43/10; H10B 43/40

(52) U.S. Cl. CPC H10B 43/27; H10B 41/10; H10B 41/27; H10B 41/41; H10B 43/10; H10B 43/40

(57) ABSTRACT

An example non-volatile memory device includes a substrate including a first cell region, a second cell region, and a connection region between the first cell region and the second cell region, a mold structure including a plurality of gate electrodes being stacked in a stepped pattern in a pad region, a trench along a profile of the mold structure on the pad region, the trench including a bottom surface having a stair shape and a first sidewall on a boundary between the pad region and a wall region, a liner film on the first sidewall of the trench, a recess in the trench and exposing a pad portion of a gate electrode, a cell contact provided at the recess and connected with the pad portion, and a cover insulating layer provided at the trench. The liner film has a different etch selectivity with respect to the cover insulating layer.

### CROSS-REFERENCE TO RELATED APPLICATION

This application claims priority under 35 U.S.C. § 119 to Korean Patent Application No. 10-2023-0135450, filed on Oct. 11, 2023, in the Korean Intellectual Property Office, the disclosure of which is incorporated by reference herein in its entirety.

### BACKGROUND

To meet high performance and cheap price demanded by consumers, it is desired to increase the integration density of non-volatile memory devices. In particular, the increase in the integration density of non-volatile memory devices is demanded because the integration density of non-volatile memory devices is an important factor in determining the price of products.

The integration density of two-dimensional (2D) or planar non-volatile memory devices is mainly determined by the area of a memory cell unit and is thus greatly influenced by the level of a micropatterning technique. However, because expensive equipment is needed to miniaturize patterns, the integration density of 2D non-volatile memory devices is still limited, although it is increasing. Therefore, three-dimensional (3D) non-volatile memory devices including memory cells arranged in three dimensions have been proposed.

### SUMMARY

The present disclosure relates to a non-volatile memory device having reduced difficulty in manufacturing processes, an electronic system having reduced difficulty in manufacturing processes, a non-volatile memory device capable of increasing device performance and reliability, and an electronic system capable of increasing device performance and reliability.

The present disclosure is not limited to what is mentioned above and will be clearly understood by those skilled in the art from the descriptions below.

In some implementations, a non-volatile memory device includes a substrate including a first cell region, a second cell region, and a connection region between the first cell region and the second cell region, a mold structure including a plurality of gate electrodes and a plurality of mold insulating layers sequentially stacked on the substrate, the plurality of gate electrodes being stacked in a stepped pattern on a pad region of the connection region, and the plurality of mold insulating layers being alternately stacked with the plurality of gate electrodes, a channel structure on the first cell region and the second cell region, the channel structure penetrating through the mold structure and crossing the plurality of gate electrodes, a trench along a profile of the mold structure on the pad region of the connection region, the trench including a bottom surface having a stair shape and a first sidewall on a boundary between the pad region of the connection region and a wall region of the connection region, a liner film on the first sidewall of the trench, a recess in the trench and exposing a pad portion of one gate electrode among the plurality of gate electrodes and the liner film on the first sidewall of the trench, a cell contact filling the recess and connected to the pad portion of the one gate electrode, and a cover insulating layer filling the trench, wherein the liner film has a different etch selectivity than the cover insulating layer.

In some implementations, a non-volatile memory device includes a peripheral circuit substrate, a peripheral circuit device on the peripheral circuit substrate, a cell substrate on the peripheral circuit substrate and including a first cell region, a second cell region apart from the first cell region in a first horizontal direction, and a connection region between the first cell region and the second cell region, the connection region including a pad region and a wall region arranged in a second horizontal direction that crosses the first horizontal direction, a mold structure including a plurality of gate electrodes being stacked in a stepped pattern on the pad region of the connection region and a plurality of mold insulating layers being alternately stacked with the plurality of gate electrodes, and the mold structure including a wall structure on the wall region of the connection region, a channel structure on the first cell region and the second cell region, the channel structure penetrating through the mold structure and crossing the plurality of gate electrodes, a cell contact on the pad region of the connection region, the cell contact including a first sidewall on a sidewall of the wall structure and being connected to a pad portion of one gate electrode among the plurality of gate electrodes, a liner film on the first sidewall of the cell contact, the liner film including a first part extending in the first horizontal direction, a cover insulating layer on the pad region, the cover insulating layer surrounding a second sidewall of the cell contact opposite to the first sidewall of the cell contact, and a dam structure between the second sidewall of the cell contact and the cover insulating layer, wherein the liner film is in contact with the first sidewall of the cell contact, and the dam structure has a different etch selectivity than the cover insulating layer.

In some implementations, an electronic system includes a main substrate, a non-volatile memory device on the main substrate, and a controller on the main substrate, the controller being electrically connected to the non-volatile memory device, wherein the non-volatile memory device includes a cell substrate including a first cell region, a second cell region, and a connection region between the first cell region and the second cell region, a mold structure including a plurality of gate electrodes and a plurality of mold insulating layers sequentially stacked on the cell substrate, the plurality of gate electrodes being stacked in a stepped pattern on a pad region of the connection region, and the plurality of mold insulating layers being alternately stacked with the plurality of gate electrodes, a channel structure on the first cell region and the second cell region, the channel structure penetrating through the mold structure and crossing the plurality of gate electrodes, a cell contact on the pad region of the connection region, the cell contact including a bottom surface and a first sidewall, the first sidewall on a boundary between the pad region of the connection region and a wall region of the connection region, the bottom surface being connected to a pad portion of one gate electrode among the plurality of gate electrodes, a liner film including a first part arranged on the first sidewall of the cell contact, a cover insulating layer on the pad region of the connection region, the cover insulating layer surrounding a second sidewall of the cell contact opposite to the first sidewall of the cell contact, and a dam structure between the second sidewall of the cell contact and the cover insulating layer, wherein the liner film is in contact with the first sidewall of the cell contact, and the liner film has a different etch selectivity than the cover insulating layer.

### BRIEF DESCRIPTION OF THE DRAWINGS

Implementations will be more clearly understood from the following detailed description taken in conjunction with the accompanying drawings.

FIG. 1 is a block diagram of an example of a non-volatile memory device.

FIG. 2 is an equivalent circuit diagram of a memory cell array of an example of a non-volatile memory device.

FIG. 3 is a perspective view of a representative configuration of an example of a non-volatile memory device.

FIG. 4 is an example plan view of the non-volatile memory device of FIG. 3.

FIG. 5 is an example cross-sectional view taken along line X1-X1′ in FIG. 4.

FIG. 6 is an example cross-sectional view taken along line Y1-Y1′ in FIG. 4.

FIG. 7 is an example cross-sectional view taken along line Y2-Y2′ in FIG. 4.

FIG. 8 is an example enlarged view of a region EX1 in FIG. 7.

FIGS. 9A, 9B, and 9C are example cross-sectional views of non-volatile memory devices.

FIGS. 10, 11, 12, and 13 are example plan views of non-volatile memory devices.

FIGS. 14A, 14B, 15A, 15B, 16A, 16B, 17A, 17B, 18A, 18B, 19A, 19B, 20A, 20B, 21A, and 21B are cross-sectional views illustrating an example of a method of manufacturing a non-volatile memory device.

FIG. 22 is a schematic diagram of an example of a data storage system including a non-volatile memory device.

FIG. 23 is a schematic perspective view of an example of a data storage system including a non-volatile memory device.

FIG. 24 is a schematic cross-sectional view of an example of a semiconductor package.

### DETAILED DESCRIPTION

Hereinafter, implementations are described in detail with reference to the accompanying drawings.

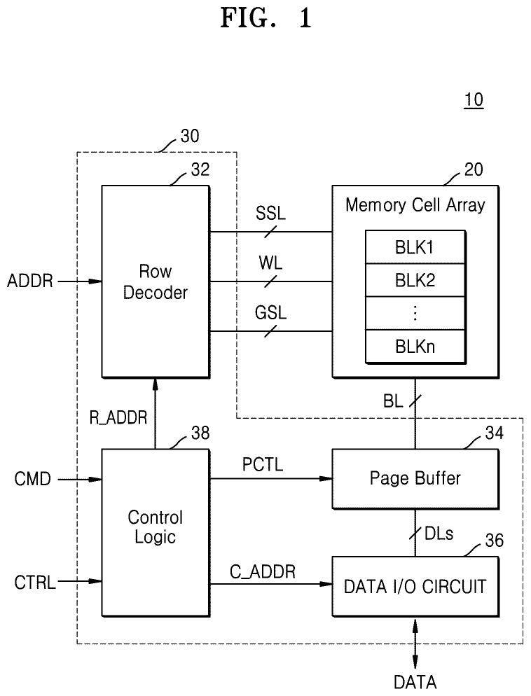

FIG. 1 is a block diagram of an example of a non-volatile memory device 10.

Referring to FIG. 1, the non-volatile memory device 10 may include a memory cell array 20 and a peripheral circuit 30. The memory cell array 20 may include a plurality of memory cell blocks, e.g., first to n-th memory cell blocks BLK1 to BLKn. Each of the first to n-th memory cell blocks BLK1 to BLKn may include a plurality of memory cells. The first to n-th memory cell blocks BLK1 to BLKn may be connected to the peripheral circuit 30 through a bit line BL, a word line WL, a string select line SSL, and a ground select line GSL.

The peripheral circuit 30 may include a row decoder 32, a page buffer 34, a data input/output (I/O) circuit 36, and a control logic 38. Although not shown in FIG. 1, the peripheral circuit 30 may further include an I/O interface, a column logic, a voltage generator, a pre-decoder, a temperature sensor, a command decoder, an address decoder, an amplifier circuit, and/or the like.

The memory cell array 20 may be connected to the page buffer 34 through the bit line BL and to the row decoder 32 through the word line WL, the string select line SSL, and the ground select line GSL. The memory cells included in the first to n-th memory cell blocks BLK1 to BLKn of the memory cell array 20 may respectively include flash memory cells. The memory cell array 20 may include a three-dimensional (3D) memory cell array. The 3D memory cell array may include a plurality of NAND strings, and each NAND string may include a plurality of memory cells respectively connected to a plurality of word lines WL vertically stacked on a substrate.

The peripheral circuit 30 may receive an address ADDR, a command CMD, and a control signal CTRL from the outside of the non-volatile memory device 10 and may exchange data with a device outside the non-volatile memory device 10.

In response to the address ADDR, the row decoder 32 may select at least one of the first to n-th memory cell blocks BLK1 to BLKn and select the word line WL, the string select line SSL, and the ground select line GSL of the selected memory cell block. The row decoder 32 may transmit, to the word line WL of the selected memory cell block, a voltage for performing a memory operation.

The page buffer 34 may be connected to the memory cell array 20 through the bit line BL. In a program operation, the page buffer 34 may operate as a write driver and apply, to the bit line BL, a voltage corresponding to data to be stored in the memory cell array 20. In a read operation, the page buffer 34 may operate as a sense amplifier and sense data stored in the memory cell array 20. The page buffer 34 may operate according to a control signal PCTL provided from the control logic 38.

The data I/O circuit 36 may be connected to the page buffer 34 through data lines DLs. In a program operation, the data I/O circuit 36 may receive program data from a memory controller and provide the program data to the page buffer 34 based on a column address C_ADDR provided from the control logic 38. In a read operation, the data I/O circuit 36 may provide read data stored in the page buffer 34 to the memory controller based on the column address C_ADDR provided from the control logic 38.

The data I/O circuit 36 may transmit an address or an instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and a column address C_ADDR to the data I/O circuit 36. The control logic 38 may generate various kinds of internal control signals, which are used in the non-volatile memory device 10, in response to the control signal CTRL. For example, the control logic 38 may adjust a voltage level applied to the word line WL and the bit line BL in a memory operation, such as a program operation or an erase operation.

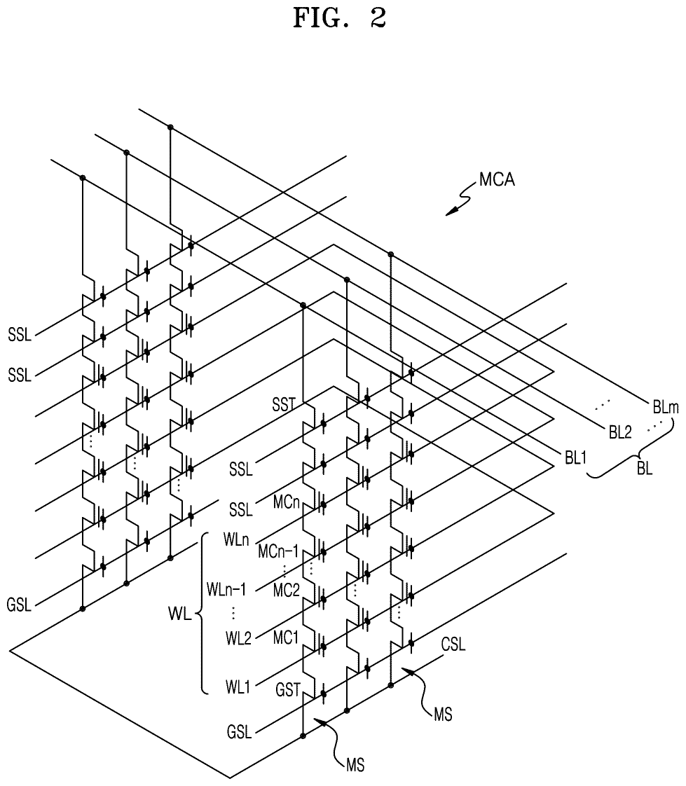

FIG. 2 is an equivalent circuit diagram of a memory cell array of an example of the non-volatile memory device 10.

Referring to FIG. 2, a memory cell array MCA may include a plurality of memory cell strings MS. The memory cell array MCA may include a plurality of bit lines BL or bit lines BL1 to BLm, a plurality of word lines WL or word lines WL1 to WLn, at least one string select line SSL, at least one ground select line GSL, a common source line CSL. The memory cell strings MS may be between the common source line CSL and the bit lines BL. Although it is illustrated in FIG. 2 that each of the memory cell strings MS includes two string select lines SSL, the present disclosure is not limited thereto. For example, each of the memory cell strings MS may include one string select line SSL.

Each of the memory cell strings MS may include a string select transistor SST, a ground select transistor GST, and a plurality of memory cell transistors MC1 to MCn. A drain region of the string select transistor SST may be connected to its corresponding one among the bit lines BL, and a source region of the ground select transistor GST may be connected to the common source line CSL. Respective source regions of a plurality of ground select transistors GST may be connected in common to the common source line CSL.

The string select transistor SST may be connected to a string select line SSL, and a ground select transistor GST may be connected to the ground select line GSL. The memory cell transistors MC1 to MCn may be respectively connected to the word lines WL1 to WLn.

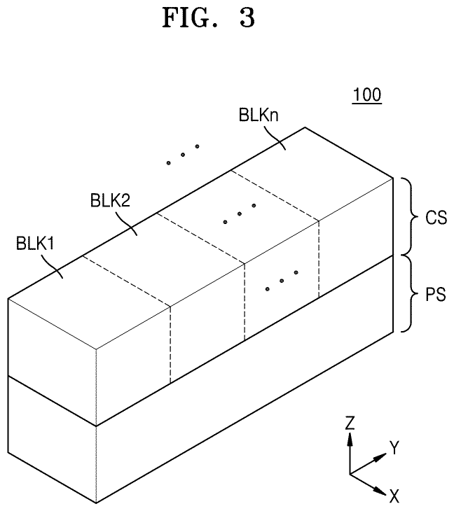

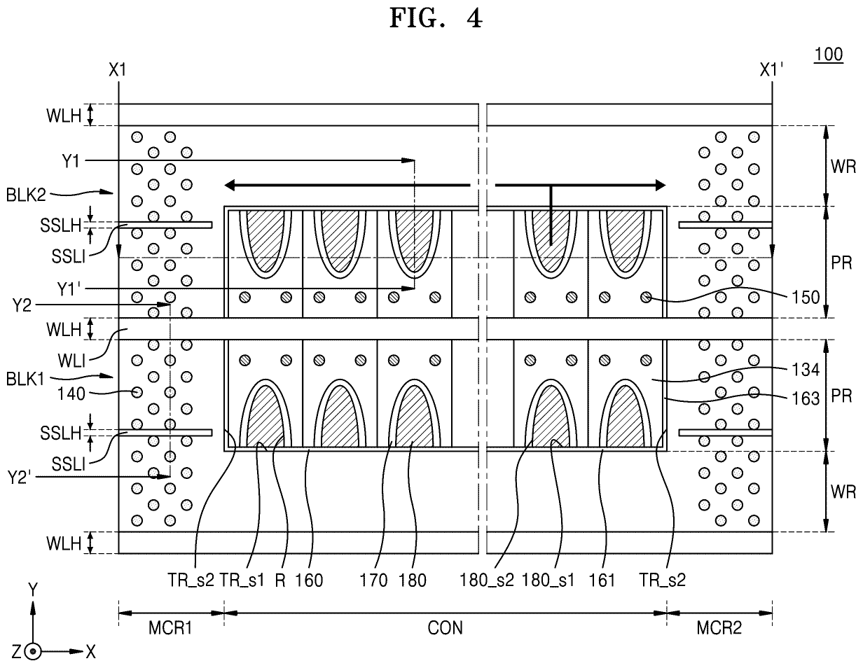

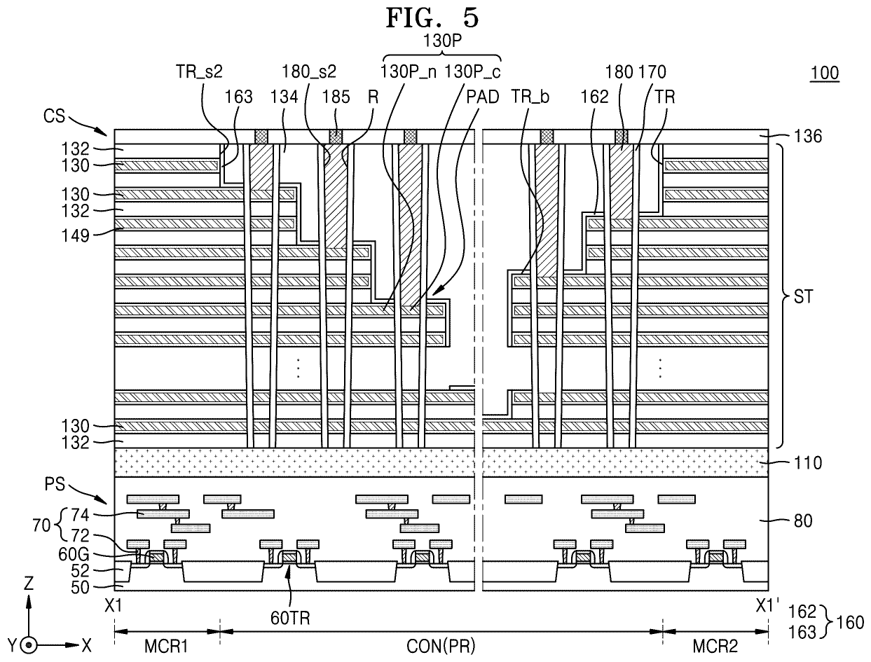

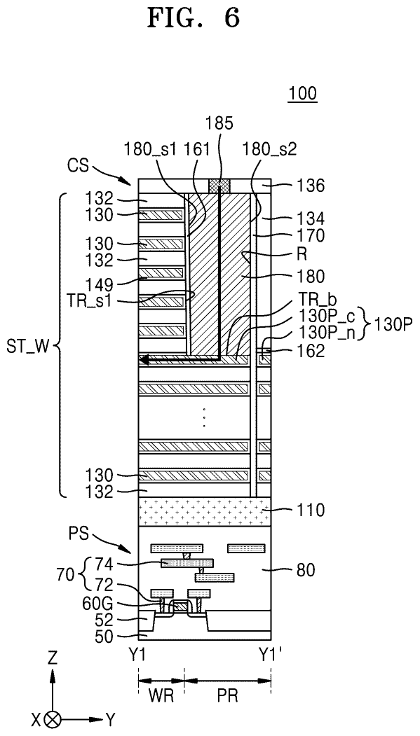

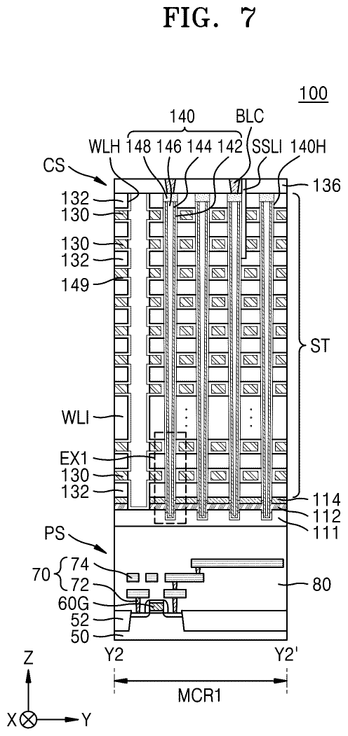

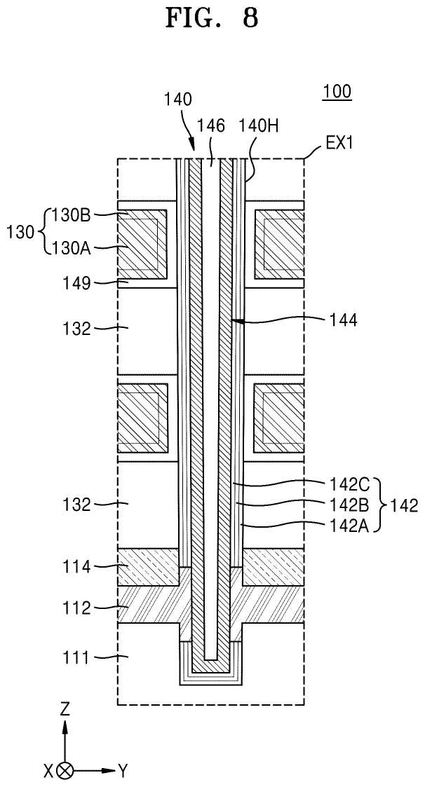

FIGS. 3 to 8 are example diagrams for describing a non-volatile memory device 100. In detail, FIG. 3 is a perspective view of a representative configuration of an example of the non-volatile memory device 100. FIG. 4 is an example plan view of the non-volatile memory device 100 of FIG. 3. FIG. 5 is an example cross-sectional view taken along line X1-X1′ in FIG. 4. FIG. 6 is an example cross-sectional view taken along line Y1-Y1′ in FIG. 4. FIG. 7 is an example cross-sectional view taken along line Y2-Y2′ in FIG. 4. FIG. 8 is an example enlarged view of a region EX1 in FIG. 7.

Referring to FIGS. 3 to 7, the non-volatile memory device 100 may include a cell array structure CS and a peripheral circuit structure PS, which overlap each other in the vertical direction (the Z direction). The cell array structure CS may include the memory cell array 20 described with reference to FIG. 1 and the peripheral circuit structure PS may include the peripheral circuit 30 described with reference to FIG. 1.

The cell array structure CS may include the first to n-th memory cell blocks BLK1 to BLKn. Each of the first to-n-th memory cell blocks BLK1 to BLKn may include memory cells arranged in three dimensions.

A substrate 50 may include a first cell region MCR1, a connection region CON, and a second cell region MCR2, which are horizontally arranged. In detail, the first cell region MCR1, the connection region CON, and the second cell region MCR2 may be arranged in a first horizontal direction (the X direction). The first cell region MCR1 may be separated from the second cell region MCR2 by the connection region CON in the first horizontal direction (the X direction). The connection region CON may include a pad region PR and a wall region WR, which are arranged in a second horizontal direction (the Y direction). In some implementations, a memory cell block (e.g., the first memory cell block BLK1) may include one pad region PR and one wall region WR, which are between the first cell region MCR1 and the second cell region MCR2.

In some implementations, respective pad regions PR of two adjacent memory cell blocks may be adjacent to each other. In detail, the pad region PR of the first memory cell block BLK1 and the pad region PR of the second memory cell block BLK2 may be adjacent to each other in the second horizontal direction (the Y direction). In some implementations, trenches TR respectively in the respective pad regions PR of two adjacent memory cell blocks may be adjacent to each other. For example, the trench TR of the first memory cell block BLK1 may be adjacent to the trench TR of the second memory cell block BLK2 in the second horizontal direction (the Y direction).

The substrate 50 may include a semiconductor material, e.g., a Group IV semiconductor, a Group III-V compound semiconductor, or a Group II-VI oxide semiconductor. For example, the Group IV semiconductor may include silicon (Si), germanium (Ge), or silicon germanium. The substrate 50 may be provided as a bulk wafer or an epitaxial layer. In some implementations, the substrate 50 may include a silicon-on-insulator (SOI) substrate or a germanium-on-insulator (GeOI) substrate.

The peripheral circuit structure PS may include a peripheral circuit transistor 60TR on the substrate 50 and a peripheral circuit wiring structure 70. An active region may be defined in the substrate 50 by an isolation film 52. A plurality of peripheral circuit transistors 60TR may be on the active region. Each of the peripheral circuit transistors 60TR may include a peripheral circuit gate 60G and a source/drain region in a portion of the substrate 50, which is at each of opposite sides of the peripheral circuit gate 60G.

The peripheral circuit wiring structure 70 may include a plurality of peripheral circuit contacts 72 and a plurality of peripheral circuit wiring layers 74. An interlayer insulating film 80 may be on the substrate 50 and may cover the peripheral circuit transistors 60TR and the peripheral circuit wiring structure 70. The peripheral circuit wiring layers 74 may have a multi-layer structure including a plurality of metal layers at different vertical levels.

A common source plate 110 may be arranged on the interlayer insulating film 80. In some implementations, the common source plate 110 may function as a source region that supplies current to vertical memory cells formed in the cell array structure CS. The common source plate 110 may be arranged across the first cell region MCR1, the connection region CON, and the second cell region MCR2 of the substrate 50.

In some implementations, the common source plate 110 may include at least one selected from the group consisting of silicon (Si), germanium (Ge), silicon germanium (SiGe), gallium arsenide (GaAs), indium gallium arsenide (InGaAs), aluminum gallium arsenide (AlGaAs), and a mixture thereof. The common source plate 110 may include a semiconductor doped with n-type impurities. The common source plate 110 may also have a crystalline structure including at least one selected from the group consisting of a monocrystalline structure, an amorphous structure, and a polycrystalline structure. In some implementations, the common source plate 110 may include polysilicon doped with n-type impurities.

A mold structure ST, in which a plurality of gate electrodes 130 and a plurality of mold insulating layers 132 are alternately arranged in the vertical direction (the Z direction), may be on the common source plate 110 in the first cell region MCR1, the connection region CON, and the second cell region MCR2.

The mold structure ST may include a wall structure ST_W, in which the gate electrodes 130 and the mold insulating layers 132 are alternately arranged in the wall region WR of the connection region CON. The mold structure ST may include the gate electrodes 130 and the mold insulating layers 132, which are alternately arranged in a stepped pattern on a pad region PR of the connection region CON.

Referring to FIG. 8, each of the gate electrodes 130 may include a buried conductive layer 130A and a conductive barrier layer 130B surrounding the top, bottom, and side surfaces of the buried conductive layer 130A. For example, the buried conductive layer 130A may include metal, such as tungsten, nickel, cobalt, or tantalum; metal silicide, such as tungsten silicide, nickel silicide, cobalt silicide, or tantalum silicide; doped polysilicon; or a combination thereof. In some implementations, the conductive barrier layer 130B may include titanium nitride, tantalum nitride, tungsten nitride, or a combination thereof.

In some implementations, the gate electrodes 130 may respectively correspond to a ground select line GSL, the word lines WL or WL1 to WLn, and at least one string select line SSL, which form a memory cell string MS (see FIG. 2). For example, the lowest gate electrode 130 may function as the ground select line GSL, two uppermost gate electrodes 130 may respectively function as string select lines SSL, and the remaining gate electrodes 130 may respectively function as the word lines WL. Accordingly, the memory cell string MS, in which a ground select transistor GST, a string select transistor SST, and the memory cell transistors MC1 to MCn therebetween are connected in series to one another, may be provided. In some implementations, at least one of the gate electrodes 130 may function as a dummy word line but is not limited thereto.

As illustrated in FIGS. 4 and 7, a plurality of gate stack isolation openings WLH may extend on the common source plate 110 in the first horizontal direction (the X direction) that is parallel with the top surface of the common source plate 110. A plurality of gate electrodes 130 between two adjacent gate stack isolation openings WLH may form a single memory cell block. For example, the first memory cell block BLK1 and the second memory cell block BLK2 are shown in FIG. 4.

A gate stack isolation insulating layer WL1 may be in each of the gate stack isolation openings WLH on the common source plate 110. The gate stack isolation insulating layer WL1 may include a silicon oxide film, a silicon nitride film, SiON, SiOCN, SiCN, or a combination thereof.

A plurality of channel structures 140 may be arranged on the first cell region MCR1 and the second cell region MCR2 and may extend in the vertical direction (the Z direction) through the gate electrodes 130 and the mold insulating layers 132. The channel structures 140 may be apart from one another by a certain distance in the first horizontal direction (the X direction), the second horizontal direction (the Y direction), and a third horizontal direction (e.g., a diagonal direction). The channel structures 140 may be arranged in a zigzag or staggered pattern.

Each of the channel structures 140 may be in a channel hole 140H in the first cell region MCR1 and the second cell region MCR2. Each of the channel structures 140 may include a gate insulating layer 142, a channel layer 144, a buried insulating layer 146, and a conductive plug 148. The gate insulating layer 142 and the channel layer 144 may be sequentially arranged on the side wall of the channel hole 140H. For example, the gate insulating layer 142 may be conformal to the side wall of the channel hole 140H, and the channel layer 144 may be conformal to the side wall and the bottom of the channel hole 140H. The buried insulating layer 146 may be on the channel layer 144 to fill the remaining space of the channel hole 140H. The conductive plug 148 may be on the upper portion of the channel hole 140H to be in contact with the channel layer 144 and block the channel hole 140H. In some implementations, the buried insulating layer 146 may be omitted, and the channel layer 144 may have a pillar shape filling the remaining portion of the channel hole 140H.

As illustrated in FIG. 8, the gate insulating layer 142 may have a structure, in which a tunneling dielectric film 142A, a charge storage film 142B, and a blocking dielectric film 142C are sequentially on the channel layer 144. The relative thicknesses of the tunneling dielectric film 142A, the charge storage film 142B, and the blocking dielectric film 142C of the gate insulating layer 142 are not limited to those illustrated in FIG. 8 and may be variously changed.

The tunneling dielectric film 142A may include silicon oxide, hafnium oxide, aluminum oxide, zirconium oxide, tantalum oxide, or the like. The charge storage film 142B may be a region, in which electrons passing from the channel layer 144 through the tunneling dielectric film 142A are stored, and may include silicon nitride, boron nitride, silicon boron nitride, or impurity-doped polysilicon. The blocking dielectric film 142C may include silicon oxide, silicon nitride, or metal oxide having a higher permittivity than silicon oxide. The metal oxide may include hafnium oxide, aluminum oxide, zirconium oxide, tantalum oxide, or a combination thereof.

In some implementations, a source layer 112 and a source support layer 114 may be sequentially formed on a cell substrate 111. The source layer 112 and the source support layer 114 may be between the cell substrate 111 and the mold structure ST. For example, the source layer 112 and the source support layer 114 may extend along the top surface of the cell substrate 111.

In some implementations, the cell substrate 111 may include a semiconductor substrate, such as a silicon substrate, a germanium substrate, or a silicon-germanium substrate. Alternatively, the cell substrate 111 may include an SOI substrate or a GeOI substrate. In some implementations, the cell substrate 111 may include impurities. For example, the cell substrate 111 may include n-type impurities (e.g., phosphorus (P) or arsenic (As)). In some implementations, the cell substrate 111 may include monocrystalline silicon.

In some implementations, the source layer 112 may be formed to be connected to the channel layer 144 of each of the channel structures 140. For example, as shown in FIG. 7, the source layer 112 may penetrate through the gate insulating layer 142 and may be in contact with the channel layer 144. The source layer 112 may be provided as a common source line (e.g., CSL in FIG. 2) of a non-volatile memory device. In some implementations, the source layer 112 may include doped polycrystalline silicon. In some implementations, the source layer 112 may include metal.

In some implementations, the channel layer 144 may be connected to the source layer 112 and separated from the cell substrate 111. In detail, the channel layer 144 may be separated from the cell substrate 111 by the source layer 112.

In some implementations, each channel structure 140 may penetrate through the source layer 112 and the source support layer 114. For example, a lower portion of the channel structure 140 may penetrate through the source support layer 114 and the source layer 112 and may be in the cell substrate 111.

Although not shown, a base insulating film may be between the cell substrate 111 and the source layer 112. For example, the base insulating film may include, but not limited to, at least one selected from the group consisting of silicon oxide, silicon nitride, and silicon oxynitride.

In some implementations, the bottom surface of the channel layer 144 may be at a lower vertical level than the top surface of the cell substrate 111, but implementations are not limited thereto.

In some implementations, a dielectric liner 149 may be between the channel structure 140 and each of the gate electrodes 130. For example, the dielectric liner 149 may be between the channel structure 140 and each gate electrode 130 and on the bottom and top surfaces of the gate electrode 130. For example, the dielectric liner 149 may be between the gate electrode 130 and the mold insulating layers 132. In some implementations, the dielectric liner 149 may include silicon oxide, silicon nitride, or metal oxide having a higher permittivity than silicon oxide. The metal oxide may include hafnium oxide, aluminum oxide, zirconium oxide, tantalum oxide, or a combination thereof. In some implementations, the dielectric liner 149 may be omitted.

In one memory cell block (e.g., the first memory cell block BLK1 or the second memory cell block BLK2), each of two uppermost gate electrodes 130 may be separated into two portions by a string separation opening SSLH according to a plan view. A string separation insulating layer SSLI may be arranged in the string separation opening SSLH. The two portions of each of the two uppermost gate electrodes 130 may be apart from each other with the string separation insulating layer SSLI therebetween in the second horizontal direction (the Y direction). The two portions of each of the two uppermost gate electrodes 130 may form the string select line SSL described with reference to FIG. 2.

A plurality of gate electrodes 130 on the pad region PR of the connection region CON may form a pad structure PAD. The pad structure PAD may refer to portions of the gate electrodes 130 arranged in a stair shape. The pad structure PAD may include a plurality of pad portions 130P respectively extending from the gate electrodes 130. Each of the pad portions 130P may include a connected portion 130P_c in contact with the cell contact 180 and a non-connected portion 130P_n not in contact with the cell contact 180.

A cover insulating layer 134 may be arranged on the pad structure PAD. An upper insulating layer 136 may be arranged on an uppermost mold insulating layer 132 and the cover insulating layer 134.

In the pad region PR of the connection region CON, the trench TR may expose the pad portions 130P. The trench TR may be arranged along the profile of the mold structure ST, which is arranged in a stair shape on the pad region PR of the connection region CON.

The trench TR may include a first sidewall TR_s1 extending in the first horizontal direction (the X direction) and a second sidewall TR_s2 extending in the second horizontal direction (the Y direction). The trench TR may include a bottom surface TR_b having a stair shape. The trench TR may expose the pad portions 130P. The bottom surface TR_b of the trench TR may expose the pad portions 130P.

The first sidewall TR_s1 of the trench TR may be on the boundary between the pad region PR and the wall region WR. As shown in FIG. 6, the first sidewall TR_s1 of the trench TR may expose a portion of a sidewall of the wall structure ST_W on the wall region WR.

The second sidewall TR_s2 of the trench TR may include a portion on the boundary between the pad region PR and the first cell region MCR1 and a portion on the boundary between the pad region PR and the second cell region MCR2. The second sidewall TR_s2 of the trench TR may include a portion arranged on the pad region PR. As shown in FIG. 5, the second sidewall TR_s2 of the trench TR may be arranged on the sidewall of the mold structure ST having a stair shape on the pad region PR. The second sidewall TR_s2 of the trench TR may have a plurality of portions that do not overlap each other in the vertical direction (the Z direction).

The bottom surface TR_b of the trench TR may expose the pad portions 130P. As shown in FIG. 6, the bottom surface TR_b of the trench TR may include a plurality of portions having different vertical levels. The bottom surface TR_b of the trench TR may be arranged in a stair shape in the first horizontal direction (the X direction).

A liner film 160, a cell contact 180, a portion of a dam structure 170, and a cover insulating layer 134 may be arranged in the trench TR.

On the pad region PR of the connection region CON, the liner film 160 may be arranged on the first sidewall TR_s1, the second sidewall TR_s2, and the bottom surface TR_b of the trench TR.

The liner film 160 may include a first part 161 on the first sidewall TR_s1 of the trench TR. The first part 161 of the liner film 160 may extend on the first sidewall TR_s1 of the trench TR in the first horizontal direction (the X direction). The first part 161 of the liner film 160 may be on the boundary between the pad region PR and the wall region WR. The first part 161 of the liner film 160 may be arranged on the portion of the sidewall of the wall structure ST_W, which is exposed by the first sidewall TR_s1 of the trench TR. In some implementations, the first part 161 of the liner film 160 may be in contact with the portion of the sidewall of the wall structure ST_W, which is exposed by the first sidewall TR_s1 of the trench TR.

The liner film 160 may further include a second part 162 on the bottom surface TR_b of the trench. The second part 162 of the liner film 160 may be arranged on the non-connected portions 130P_n of the pad portions 130P. The second part 162 of the liner film 160 may be between each of the non-connected portions 130P_n of the pad portions 130P and the cover insulating layer 134. The second part 162 of the liner film 160 may not be arranged on the connected portion 130P_c of each of the pad portions 130P. As shown in FIG. 5, the second part 162 of the liner film 160 may include a plurality of portions at different vertical levels. The second part 162 of the liner film 160 may be arranged in a stair shape in the first horizontal direction (the X direction).

The liner film 160 may further include a third part 163 on the second sidewall TR_s2 of the trench TR. The third part 163 of the liner film 160 may extend on the second sidewall TR_s2 of the trench TR in the second horizontal direction (the Y direction). The third part 163 of the liner film 160 may include a portion on the boundary between the pad region PR and the first cell region MCR1 and a portion on the boundary between the pad region PR and the second cell region MCR2. As shown in FIG. 5, the third part 163 of the liner film 160 may be arranged on the sidewall of the mold structure ST having a stair shape on the pad region PR. The third part 163 of the liner film 160 may include a plurality of portions that do not overlap each other in the vertical direction (the Z direction).

The liner film 160 may include oxide. The liner film 160 may have a different etch selectivity with respect to the cover insulating layer 134. For example, the liner film 160 may include a material that has a low etch selectivity with respect to the cover insulating layer 134. For example, the liner film 160 may include borophosphosilicate glass (BPSG). The liner film 160 may have a thickness of about 200 Å to about 1000 Å. For example, the liner film 160 may have a thickness of about 1000 Å or more.

In the pad region PR of the connection region CON, a plurality of recesses R may respectively expose the pad portions 130P of the gate electrodes 130. In detail, a recess R may partially expose a pad portion 130P. For example, the recess R may expose the connected portion 130P_c of the pad portion 130P.

The recess R may expose the first part 161 of the liner film 160 arranged on the first sidewall TR_s1 of the trench TR.

On the pad region PR of the connection region CON, a plurality of cell contacts 180 may be arranged to respectively fill the recesses R. Each of the cell contacts 180 may be connected to one of the pad portions 130P of the gate electrodes 130. Each cell contact 180 may be connected to the connected portion 130P_c of the pad portion 130P of one of the gate electrodes 130.

The cell contact 180 may include a first sidewall 180_s1 on the first sidewall TR_s1 of the trench TR and a second sidewall 180_s2 opposite to the first sidewall 180_s1.

The first sidewall 180_s1 of the cell contact 180 may extend on the first sidewall TR_s1 of the trench TR in the first horizontal direction (the X direction). The first sidewall 180_s1 of the cell contact 180 may be arranged on the portion of the sidewall of the wall structure ST_W, which is exposed by the first sidewall TR_s1 of the trench TR. The first sidewall 180_s1 of the cell contact 180 may be arranged on the first part 161 of the liner film 160 on the first sidewall TR_s1 of the trench TR. The first sidewall 180_s1 of the cell contact 180 may be in contact with the first part 161 of the liner film 160.

The second sidewall 180_s2 of the cell contact 180 may be surrounded by the dam structure 170. The second sidewall 180_s2 of the cell contact 180 may be in contact with the dam structure 170.

In some implementations, according to a plan view, the second sidewall 180_s2 of the cell contact 180 may be concave with respect to the first sidewall 180_s1 of the cell contact 180. The second sidewall 180_s2 of the cell contact 180 may be a concave curved surface with respect to the first sidewall 180_s1 of the cell contact 180.

In a plan view, the cell contact 180 may have a bow shape. The first sidewall 180_s1 and the second sidewall 180_s2 of the cell contact 180 may form the bow shape. In detail, the first sidewall 180_s1 of the cell contact 180 may form the string of the bow shape. The second sidewall 180_s2 of the cell contact 180 may form the arc of the bow shape. For example, the cell contact 180 may have a semicircular shape.

The cell contact 180 may not penetrate through the mold structure ST. The cell contact 180 may extend in the recess R and reach the pad portion 130P of the gate electrode 130.

The cell contact 180 may include metal, such as tungsten, nickel, cobalt, or tantalum; metal silicide, such as tungsten silicide, nickel silicide, cobalt silicide, or tantalum silicide; doped polysilicon; or a combination thereof.

In some implementations, the cell contact 180 may transmit an electrical signal to the gate electrode 130. In detail, when an electrical signal is applied to the cell contact 180, the electrical signal may be transmitted to the pad portion 130P that is connected to the cell contact 180. The electrical signal transmitted to the pad portion 130P may be transmitted to the wall structure ST_W on the wall region WR in the second horizontal direction (the Y direction). In detail, the electrical signal may be transmitted to the gate electrode 130 that is at the same vertical level as and connected to the pad portion 130P among the plurality of gate electrodes 130 of the wall structure ST_W. Subsequently, the electrical signal may be bidirectionally transmitted in the first horizontal direction (the X direction). In detail, the electrical signal may be transmitted in the first horizontal direction (the X direction) to a gate electrode 130 on the first cell region MCR1 and a gate electrode 130 on the second cell region MCR2.

On the pad region PR of the connection region CON, the cover insulating layer 134 may be arranged to fill the trench TR. The cover insulating layer 134 may fill the trench TR except for the liner film 160, the dam structure 170, and the recess R.

The cover insulating layer 134 may be arranged on the pad portion 130P. In detail, the cover insulating layer 134 may be arranged on the non-connected portion 130P_n of the pad portion 130P. The cover insulating layer 134 may be arranged on the mold structure ST with the liner film 160 between the cover insulating layer 134 and the mold structure ST.

The cover insulating layer 134 may surround the cell contact 180 with the dam structure 170 between the cover insulating layer 134 and the cell contact 180. In detail, the cover insulating layer 134 may surround the second sidewall 180_s2 of the cell contact 180 with the dam structure 170 between the cover insulating layer 134 and the second sidewall 180_s2 of the cell contact 180.

On the pad region PR of the connection region CON, the dam structure 170 may be arranged to penetrate through the cover insulating layer 134, the plurality of gate electrodes 130, and the plurality of mold insulating layers 132. The dam structure 170 may penetrate the liner film 160 on the pad portion 130P. The dam structure 170 may penetrate the second part 162 of the liner film 160. The dam structure 170 may surround the second sidewall 180_s2 of the cell contact 180. The dam structure 170 may be in contact with the second sidewall 180_s2 of the cell contact 180. The dam structure 170 may be between the cell contact 180 and the cover insulating layer 134. The dam structure 170 may be between the second sidewall 180_s2 of the cell contact 180 and the cover insulating layer 134.

The dam structure 170 may include oxide. The dam structure 170 may have a different etch selectivity with respect to the cover insulating layer 134. For example, the dam structure 170 may include a material that has a low etch selectivity with respect to the cover insulating layer 134. The dam structure 170 may include the same material as the liner film 160.

In the pad region PR of the connection region CON, a plurality of support structures 150 may be arranged to penetrate through the cover insulating layer 134, the gate electrodes 130, and the mold insulating layers 132. In a plan view, each of the support structures 150 may be adjacent to the cell contact 180. The support structures 150 may include at least one of silicon oxide and silicon oxynitride. The support structures 150 may be formed to prevent the gate electrodes 130 from leaning or bending in the manufacturing processes of the non-volatile memory device 100 and securing the structural stability of the gate electrodes 130.

In the first cell region MCR1 and the second cell region MCR2, a bit line contact BLC may penetrate through the upper insulating layer 136 and may be in contact with the conductive plug 148 of the channel structure 140. A bit line may be arranged on the bit line contact BLC.

In the connection region CON, an upper contact 185 may penetrate through the upper insulating layer 136 and may be in contact with the cell contact 180. The upper contact 185 may be arranged on the top surface of the cell contact 180.

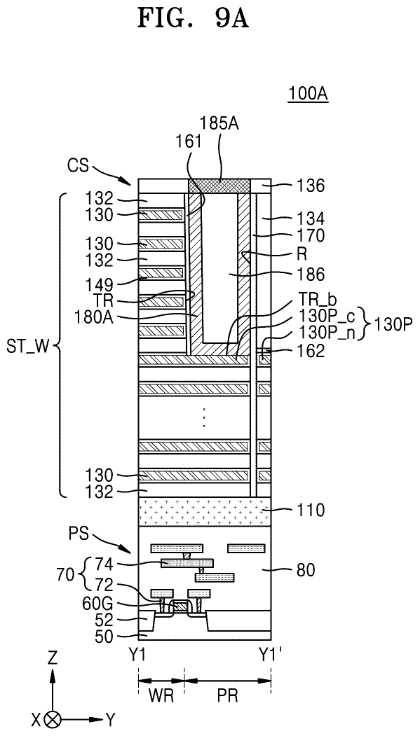

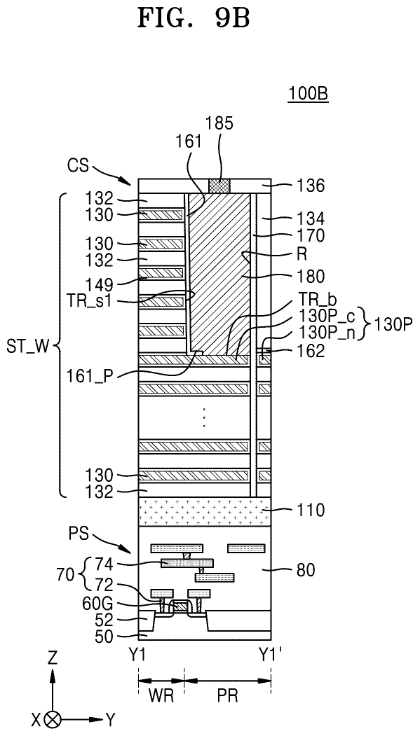

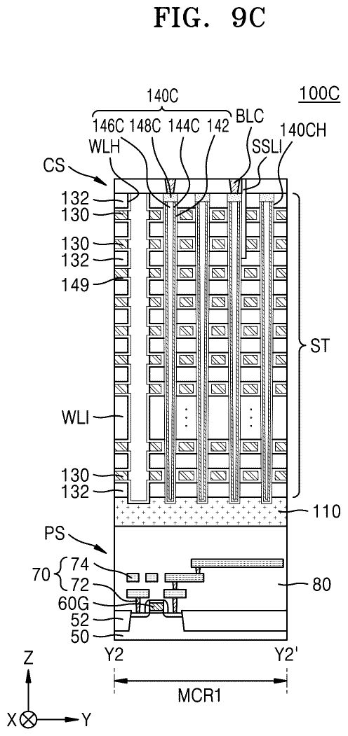

FIGS. 9A, 9B, and 9C are example cross-sectional views of non-volatile memory devices 100A, 100B, and 100C. Descriptions below focus on the differences from the non-volatile memory device 100 described above with reference to FIGS. 3 to 8.

Referring to FIG. 9A, the non-volatile memory device 100A may be provided. FIG. 9A is a cross-sectional view corresponding to the cross-section taken along line Y1-Y1′ in FIG. 4.

The non-volatile memory device 100A may include a cell contact 180A and a filling layer 186 in a recess R. The cell contact 180A may be conformally arranged on the sidewalls and bottom surface of the recess R. The cell contact 180A may be connected to the connected portion 130P_c of the pad portion 130P on the bottom surface of the recess R. The filling layer 186 may be arranged on the cell contact 180A to fill the remaining space of the recess R. An upper contact 185A may be arranged on the top surface of the cell contact 180A. The upper contact 185A may penetrate through the upper insulating layer 136 and may be in contact with the cell contact 180A.

Referring to FIG. 9B, the non-volatile memory device 100B is provided. FIG. 9B is a cross-sectional view corresponding to the cross-section taken along line Y1-Y1′ in FIG. 4.

The non-volatile memory device 100B may include the liner film 160, which extends on the inner wall and bottom surface of the trench TR. In detail, the liner film 160 may include the first part 161 extending on the first sidewall TR_s1 of the trench TR. The first part 161 of the liner film 160 may include a protrusion 161_P, which extends on the pad portion 130P in the second horizontal direction (the Y direction). The protrusion 161_P may extend from a lower portion of the first part 161 of the liner film 160 in the second horizontal direction (the Y direction).

Referring to FIG. 9C, the non-volatile memory device 100C is provided. FIG. 9C is a cross-sectional view corresponding to the cross-section taken along line Y2-Y2′ in FIG. 4.

The non-volatile memory device 100C may include a plurality of channel structures 140C, which extend from the top surface of the common source plate 110 in the vertical direction (the Z direction) and penetrate through the gate electrodes 130 and the mold insulating layers 132 on the first cell region MCR1 and the second cell region MCR2.

Each of the channel structures 140C may be in a channel hole 140CH on the first cell region MCR1 and the second cell region MCR2. Each of the channel structures 140C may include a gate insulating layer 142, a channel layer 144C, a buried insulating layer 146C, and a conductive plug 148C.

The channel layer 144C may be in contact with the top surface of the common source plate 110 at the bottom of the channel hole 140CH. In some implementations, the bottom surface of the channel layer 144C may be at a lower vertical level than the top surface of the common source plate 110, as shown in FIG. 9C. However, implementations are not limited thereto.

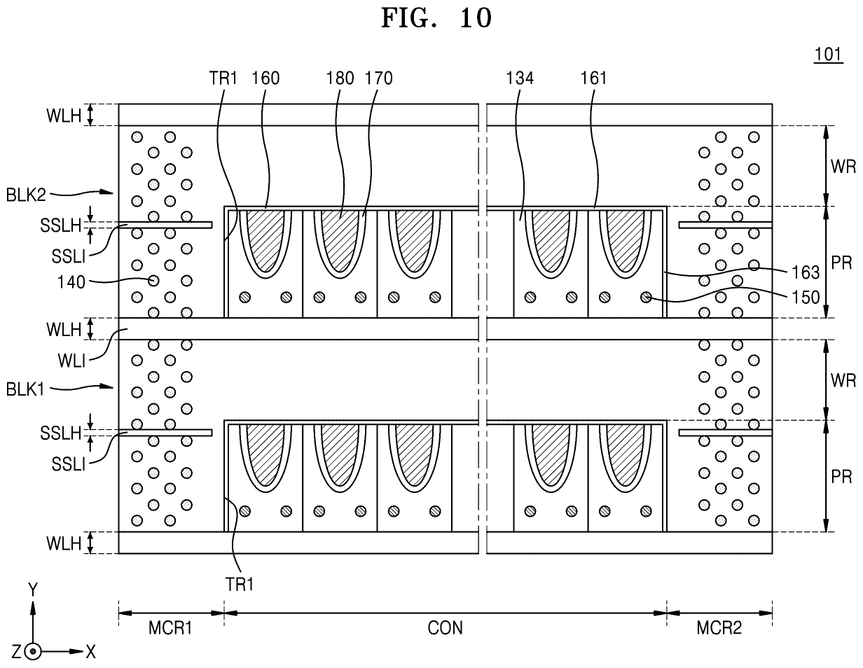

FIGS. 10, 11, 12, and 13 are example plan views of non-volatile memory devices 101, 102, 103, and 104. Descriptions below focus on the differences from the non-volatile memory device 100 described above with reference to FIGS. 3 to 8.

Referring to FIG. 10, the non-volatile memory device 101 may be provided. In some implementations, the respective pad regions PR of two adjacent memory cell blocks of the non-volatile memory device 101 may be apart from each other with a wall region WR therebetween. In detail, the pad region PR of the first memory cell block BLK1 may be apart from the pad region PR of the second memory cell block BLK2 with the wall region WR of the first memory cell block BLK1 therebetween in the second horizontal direction (the Y direction).

In some implementations, trenches TR1 respectively on the respective pad regions PR of two adjacent memory cell blocks may be apart from each other with the wall region WR therebetween. For example, the trench TR1 of the first memory cell block BLK1 may be apart from the trench TR1 of the second memory cell block BLK2 with the wall region WR of the first memory cell block BLK1 therebetween in the second horizontal direction (the Y direction).

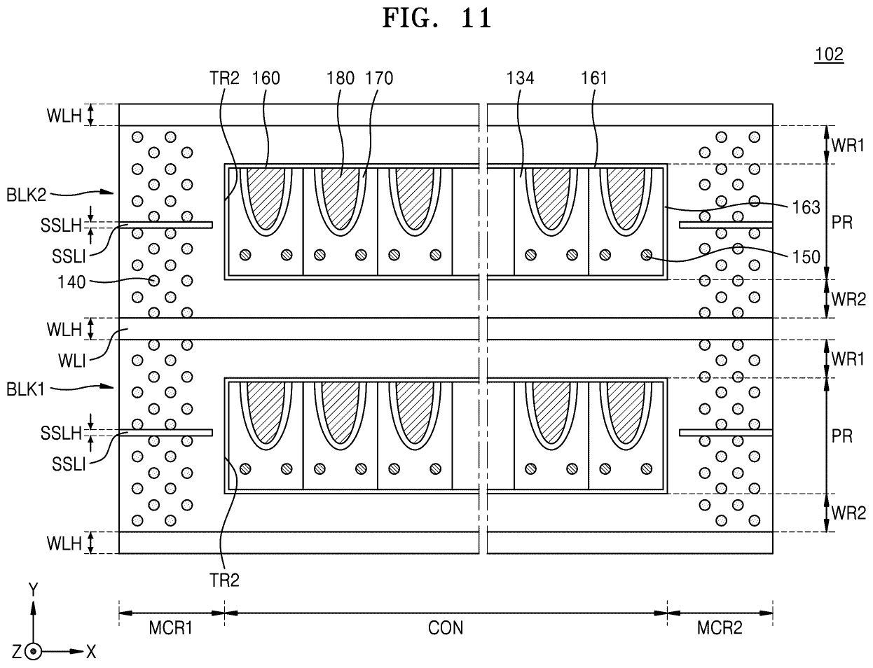

Referring to FIG. 11, the non-volatile memory device 102 may be provided. In some implementations, a memory cell block of the non-volatile memory device 102 may include one pad region PR and two wall regions, e.g., first and second wall regions WR1 and WR2. In detail, the pad region PR of the first memory cell block BLK1 may be between the first and second wall regions WR1 and WR2 thereof. The first wall region WR1 and the second wall region WR2 of the first memory cell block BLK1 may be apart from each other with the pad region PR of the first memory cell block BLK1 therebetween in the second horizontal direction (the Y direction). In detail, the pad region PR of the second memory cell block BLK2 may be between the first and second wall regions WR1 and WR2 thereof. The first wall region WR1 and the second wall region WR2 of the second memory cell block BLK2 may be apart from each other with the pad region PR of the second memory cell block BLK2 therebetween in the second horizontal direction (the Y direction).

In some implementations, trenches TR2 on the pad region PR of a memory cell block may be between the first and second wall regions WR1 and WR2 thereof. In detail, the trench TR2 of the first memory cell block BLK1 may be between the first and second wall regions WR1 and WR2 thereof. The first wall region WR1 and the second wall region WR2 of the first memory cell block BLK1 may be apart from each other with the trench TR2 of the first memory cell block BLK1 therebetween in the second horizontal direction (the Y direction). In detail, the trench TR2 of the second memory cell block BLK2 may be between the first and second wall regions WR1 and WR2 thereof. The first wall region WR1 and the second wall region WR2 of the second memory cell block BLK2 may be apart from each other with the trench TR2 of the second memory cell block BLK2 therebetween in the second horizontal direction (the Y direction).

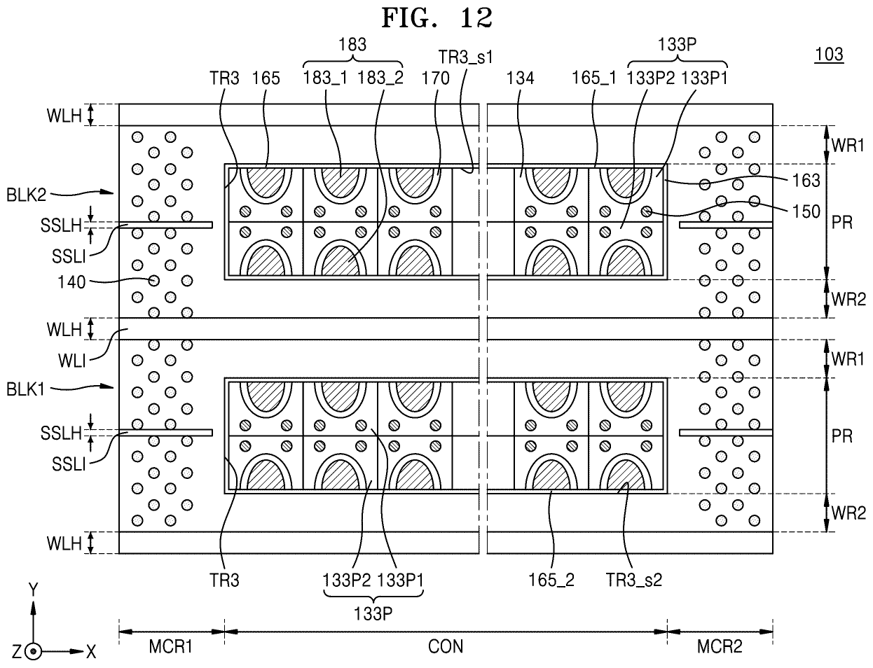

Referring to FIG. 12, the non-volatile memory device 103 may be provided. In some implementations, a memory cell block of the non-volatile memory device 103 may include one pad region PR and two wall regions, e.g., first and second wall regions WR1 and WR2. In detail, the pad region PR of each of the first memory cell block BLK1 and the second memory cell block BLK2 may be between the first and second wall regions WR1 and WR2 thereof. In detail, a trench TR3 on the pad region PR of each of the first memory cell block BLK1 and the second memory cell block BLK2 may be between the first and second wall regions WR1 and WR2 thereof.

For example, the trench TR3 may include a first sidewall TR3_s1 adjacent to the first wall region WR1 and a second sidewall TR3_s2 adjacent to the second wall region WR2. The first sidewall TR3_s1 of the trench TR3 may expose a portion of a sidewall of a first wall structure on the first wall region WR1. The second sidewall TR3_s2 of the trench TR3 may expose a portion of a sidewall of a second wall structure on the second wall region WR2. The first sidewall TR3_s1 and the second sidewall TR3_s2 of the trench TR3 may extend in the first horizontal direction (the X direction). The first sidewall TR3_s1 and the second sidewall TR3_s2 of the trench TR3 may face each other in the second horizontal direction (the Y direction).

A liner film 165 of the non-volatile memory device 103 may be arranged on the sidewall and bottom surface of the trench TR3. In detail, the liner film 165 may include a first sub portion 165_1 arranged on the first sidewall TR3_s1 of the trench TR3 and a second sub portion 165_2 arranged on the second sidewall TR3_s2 of the trench TR3.

In some implementations, the trench TR3 may expose a plurality of pad portions 133P. In detail, the bottom surface of the trench TR3 may expose the pad portions 133P. The pad portions 133P may include a first pad portion 133P1 adjacent to the first wall region WR1 and a second pad portion 133P2 adjacent to the second wall region WR2. The vertical levels of the first pad portion 133P1 and the second pad portion 133P2, which overlap each other in the second horizontal direction (the Y direction), may be different from each other. The first pad portion 133P1 and the second pad portion 133P2, which overlap each other in the second horizontal direction (the Y direction), may be respectively connected to different gate electrodes 130 (see FIGS. 5 to 7).

In some implementations, a plurality of cell contacts 183 may be arranged in the trench TR3 to be respectively connected to the pad portions 133P. The cell contacts 183 may include a first cell contact 183_1 adjacent to the first wall region WR1 and a second cell contact 183_2 adjacent to the second wall region WR2. The first cell contact 183_1 may be connected to the first pad portion 133P1. The second cell contact 183_2 may be connected to the second pad portion 133P2. An electrical signal applied to the first cell contact 183_1 may be transmitted to the first pad portion 133P1 and then to gate electrodes 130 on the first cell region MCR1 and the second cell region MCR2 through a wall structure on the first wall region WR1. An electrical signal applied to the second cell contact 183_2 may be transmitted to the second pad portion 133P2 and then to gate electrodes 130 on the first cell region MCR1 and the second cell region MCR2 through a wall structure on the second wall region WR2.

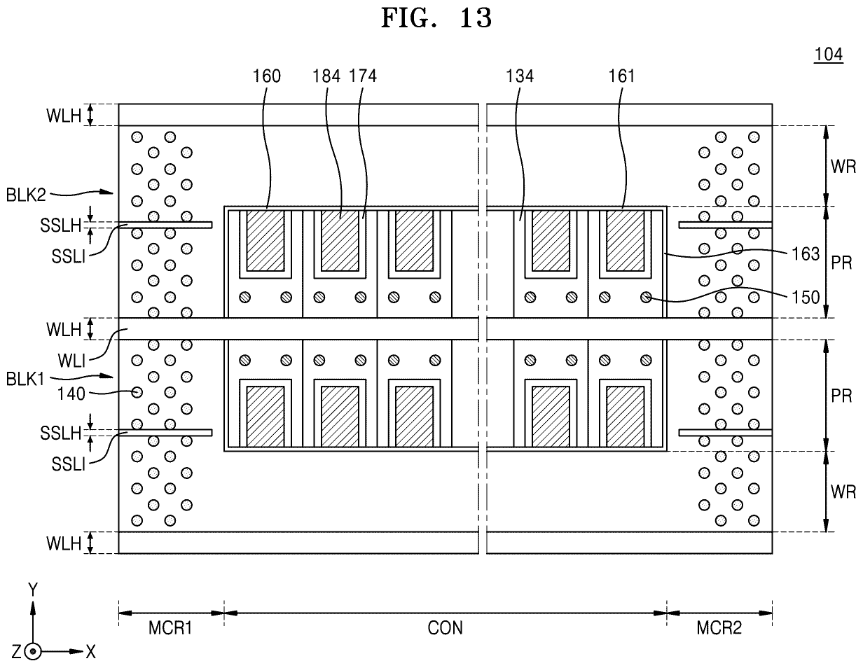

Referring to FIG. 13, the non-volatile memory device 104 may be provided. In some implementations, the non-volatile memory device 104 may include a plurality of cell contacts 184 and a dam structure 174 surrounding each of the cell contacts 184 on a pad region PR.

In a plan view, each cell contact 184 may have a quadrilateral shape. The sidewalls of the cell contact 184 may form the quadrilateral shape together with the liner film 160. For example, the cell contact 184 may have a rectangular shape. For example, the cell contact 184 may have a square shape.

Similarly, the dam structure 174 may form a quadrilateral shape together with the liner film 160. For example, the dam structure 174 may form a rectangular shape together with the liner film 160. For example, the dam structure 174 may form a square shape together with the liner film 160.

In some implementations, each of the non-volatile memory devices 100, 100A, 100B, 100C, 101, 102, 103, and 104 described with reference to FIGS. 1 to 13 may have a chip-to-chip (C2C) structure. The C2C structure may refer to a structure formed by manufacturing an upper chip including a cell region on a first wafer, manufacturing a lower chip including a peripheral circuit region on a second wafer, different from the first wafer, and then connecting the upper chip to the lower chip in a bonding manner. For example, the bonding manner may include a method of electrically connecting a bonding metal formed on an uppermost metal layer of the upper chip to a bonding metal formed on an uppermost metal layer of the lower chip. For example, when the bonding metal includes copper (Cu), the bonding manner may be Cu—Cu bonding, and the bonding metal may also include aluminum (Al) or tungsten (W).

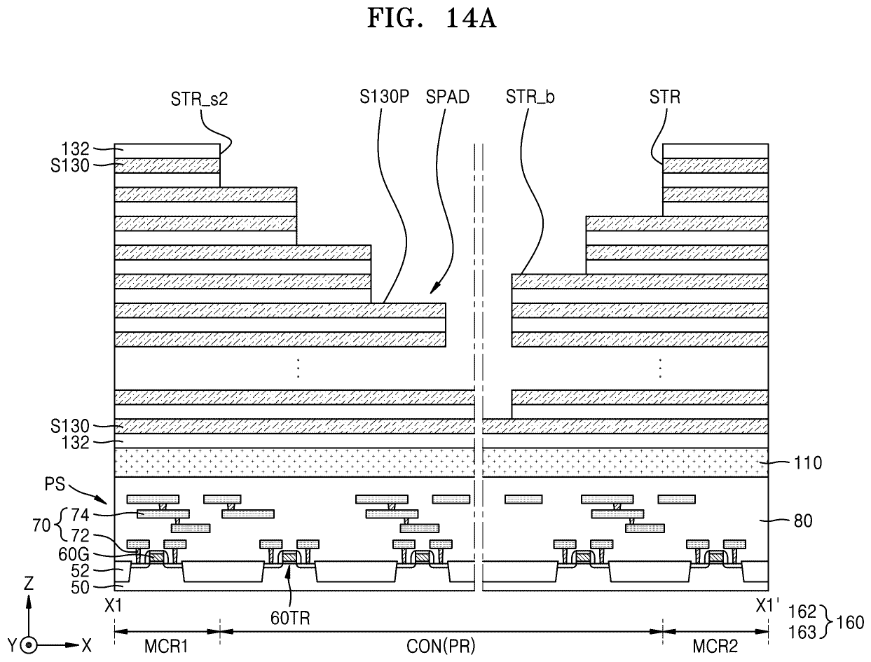

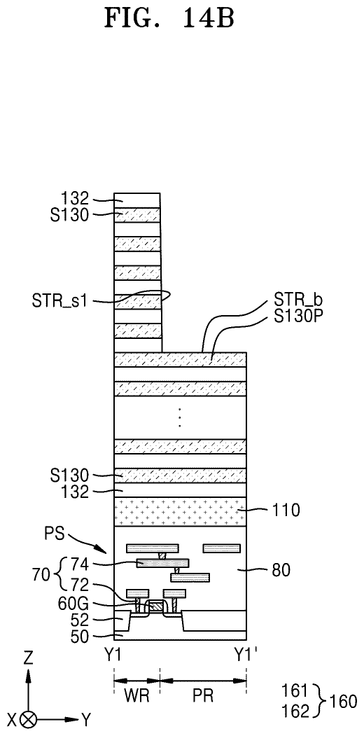

FIGS. 14A, 14B, 15A, 15B, 16A, 16B, 17A, 17B, 18A, 18B, 19A, 19B, 20A, 20B, 21A, and 21B are cross-sectional views illustrating an example of a method of manufacturing the non-volatile memory device 100. In detail, FIGS. 14A, 15A, 16A, 17A, 18A, 19A, 20A, and 21A are cross-sectional views corresponding to the cross-section taken along line X1-X1′ in FIG. 4, and FIGS. 14B, 15B, 16B, 17B, 18B, 19B, 20B, and 21B are cross-sectional views corresponding to the cross-section taken along line Y1-Y1′ in FIG. 4.

Referring to FIGS. 14A and 14B, a peripheral circuit structure PS may be formed on the substrate 50. In implementations, the substrate 50 may correspond to a monocrystalline silicon substrate. A plurality of peripheral circuit transistors 60TR may be formed on the substrate 50. The peripheral circuit wiring structure 70 and the interlayer insulating film 80 may be formed to be electrically connected to the peripheral circuit transistors 60TR.

Subsequently, the common source plate 110 may be formed on the interlayer insulating film 80. In some implementations, the common source plate 110 may be formed using a semiconductor doped with n-type impurities.

Thereafter, a plurality of mold insulating layers 132 and a plurality of sacrificial layers S130 may be alternately formed on the common source plate 110. In some implementations, the mold insulating layers 132 may include an insulating material, such as silicon oxide or silicon oxynitride, and the sacrificial layers S130 may include silicon nitride, silicon oxynitride, or impurity-doped polysilicon.

A preliminary trench STR may be formed by sequentially patterning the mold insulating layers 132 and the sacrificial layers S130 on the connection region CON. Accordingly, a preliminary pad structure SPAD may be formed. In some implementations, the preliminary pad structure SPAD may be formed to have steps having different top surface levels in the first horizontal direction (the X direction). For example, the preliminary pad structure SPAD may include a plurality of preliminary pad portions S130P.

In some implementations, the preliminary trench STR may include a first sidewall STR_s1 extending in the first horizontal direction (the X direction), a second sidewall STR_s2 extending in the second horizontal direction (the Y direction), and a bottom surface STR_b exposing the preliminary pad portions S130P. The first sidewall STR_s1 of the preliminary trench STR may partially expose the sidewalls of the mold insulating layers 132 and the sacrificial layers S130 on the wall region WR. The bottom surface STR_b of the preliminary trench STR may be arranged in a stair shape in the first horizontal direction (the X direction).

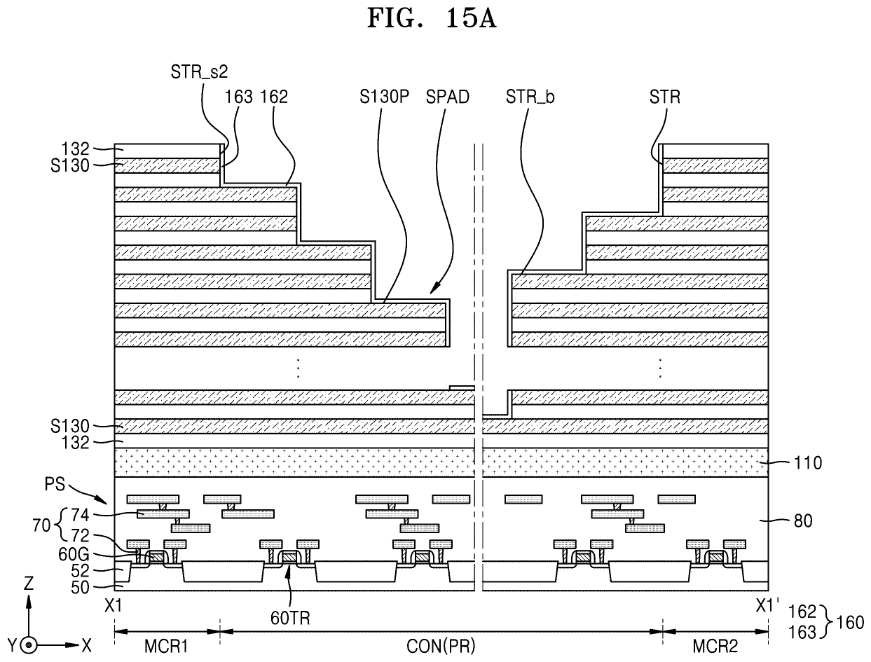

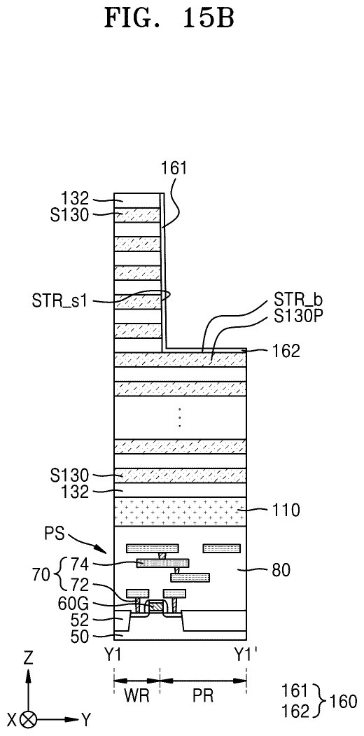

Referring to FIGS. 15A and 15B, the liner film 160 may be formed on the first sidewall STR_s1, the second sidewall STR_s2, and the bottom surface STR_b of the preliminary trench STR.

The first part 161 of the liner film 160 may extend on the first sidewall STR_s1 of the preliminary trench STR in the first horizontal direction (the X direction). The first part 161 of the liner film 160 may be partially arranged on the sidewalls of the mold insulating layers 132 and the sacrificial layers S130, which are exposed by the first sidewall STR_s1 of the preliminary trench STR, on the boundary between the pad region PR and the wall region WR.

The second part 162 of the liner film 160 may be arranged on the bottom surface STR_b of the preliminary trench STR. The second part 162 of the liner film 160 may be arranged on the preliminary pad portions S130P. The second part 162 of the liner film 160 may be arranged in a stair shape in the first horizontal direction (the X direction).

The third part 163 of the liner film 160 may be arranged on the second sidewall STR_s2 of the preliminary trench STR. The third part 163 of the liner film 160 may be partially arranged on the sidewalls of the mold insulating layers 132 and the sacrificial layers S130, which are exposed by the second sidewall STR_s2 of the preliminary trench STR, on the boundary between the pad region PR and each of the first and second cell regions MCR1 and MCR2.

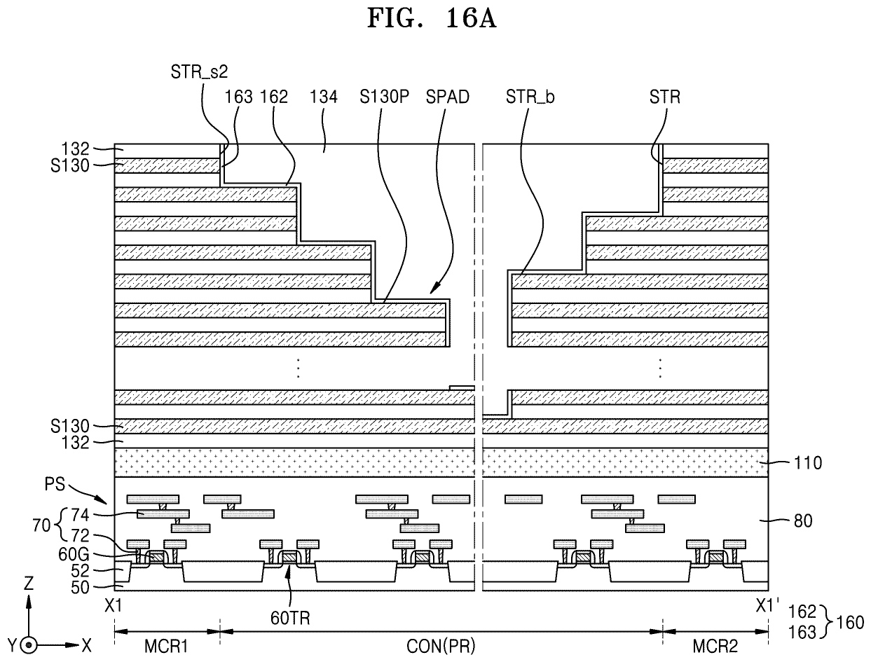

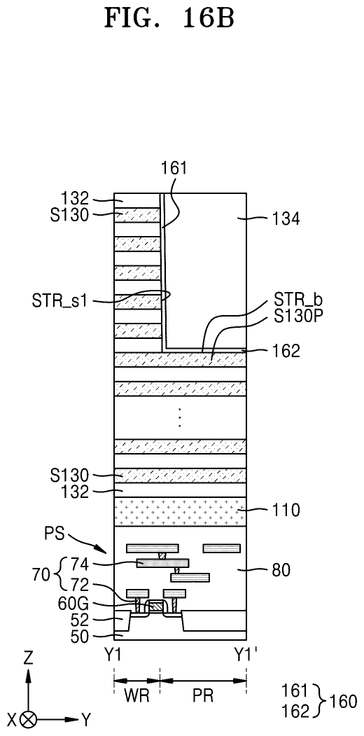

Referring to FIGS. 16A and 16B, the cover insulating layer 134 may be formed to fill the preliminary trench STR. The cover insulating layer 134 may be arranged on the liner film 160.

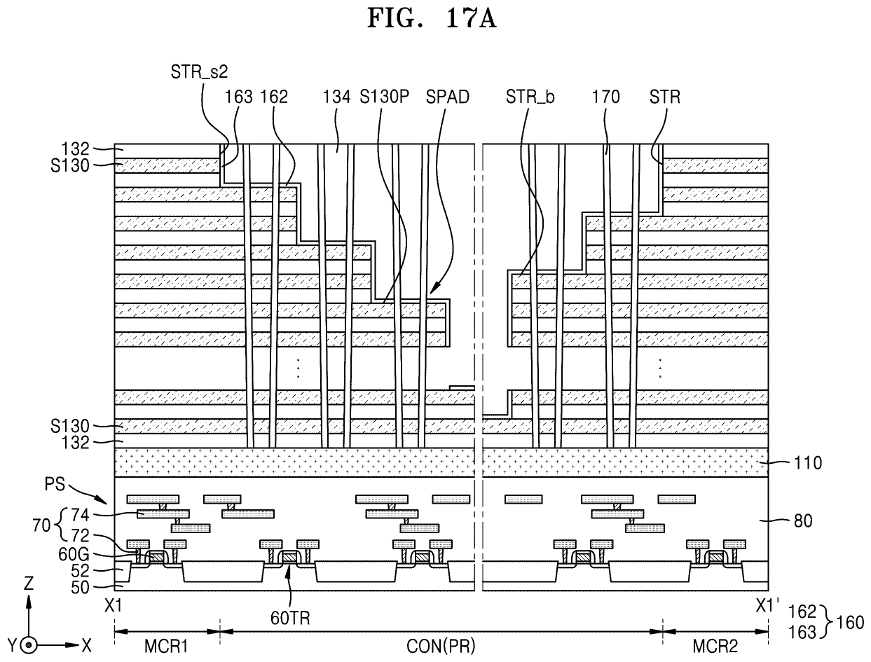

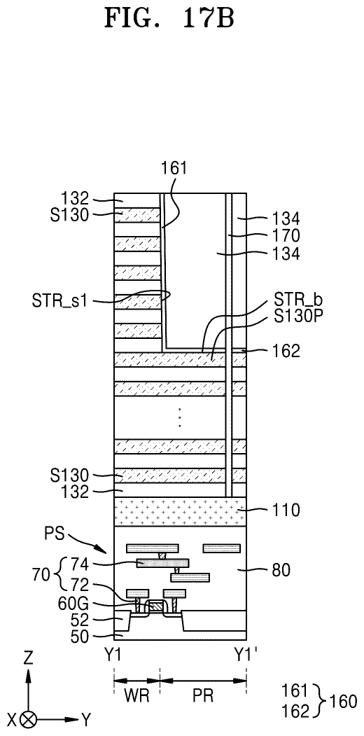

Referring to FIGS. 17A and 17B, the dam structure 170 may be formed to penetrate through the cover insulating layer 134, the sacrificial layers S130, and the mold insulating layers 132.

In detail, a plurality of through holes penetrating through the cover insulating layer 134, the sacrificial layers S130, and the mold insulating layers 132 may be formed to form the dam structure 170. For example, a plurality of through holes penetrating through one preliminary pad portion S130P may be formed. Subsequently, a process of forming a dam hole may be performed by expanding the through holes. In detail, by etching the cover insulating layer 134, the sacrificial layers S130, and the mold insulating layers 132, which are exposed by the sidewalls of the through holes, one dam hole may be formed. As a result, one dam hole penetrating through one preliminary pad portion S130P may be formed. Subsequently, the dam structure 170 may be formed by filing the dam hole with an insulating material. The dam structure 170 may include a material that has a different etch selectivity with respect to the cover insulating layer 134. The dam structure 170 may include a material that has a low etch selectivity with respect to the cover insulating layer 134. The dam structure 170 may include the same material as the liner film 160.

During the formation of the dam structure 170, a process of forming a plurality of channel structures 140 (see FIGS. 4 and 7) may be performed on the first cell region MCR1 and the second cell region MCR2. During the formation of the dam structure 170, a process of forming a plurality of support structures 150 (see FIG. 4) penetrating through the cover insulating layer 134, the sacrificial layers S130, and the mold insulating layers 132 may also be performed.

In some implementations, the process of forming the dam structure 170 may be separately performed from the process of forming the channel structures 140 on the first cell region MCR1 and the second cell region MCR2 and the process of forming the support structures 150 on the connection region CON. For example, after the channel structures 140 and the support structures 150 are formed, the dam structure 170 may be formed on the pad region PR of the connection region CON. Alternatively, after the dam structure 170 is formed on the pad region PR of the connection region CON, the channel structures 140 and the support structures 150 may be formed.

For example, to manufacture the non-volatile memory device 104 described with reference to FIG. 13, the dam structure 170 may be formed on the pad region PR of the connection region CON after the channel structures 140 and the support structures 150 are formed, or the channel structures 140 and the support structures 150 may be formed after the dam structure 170 is formed on the pad region PR of the connection region CON.

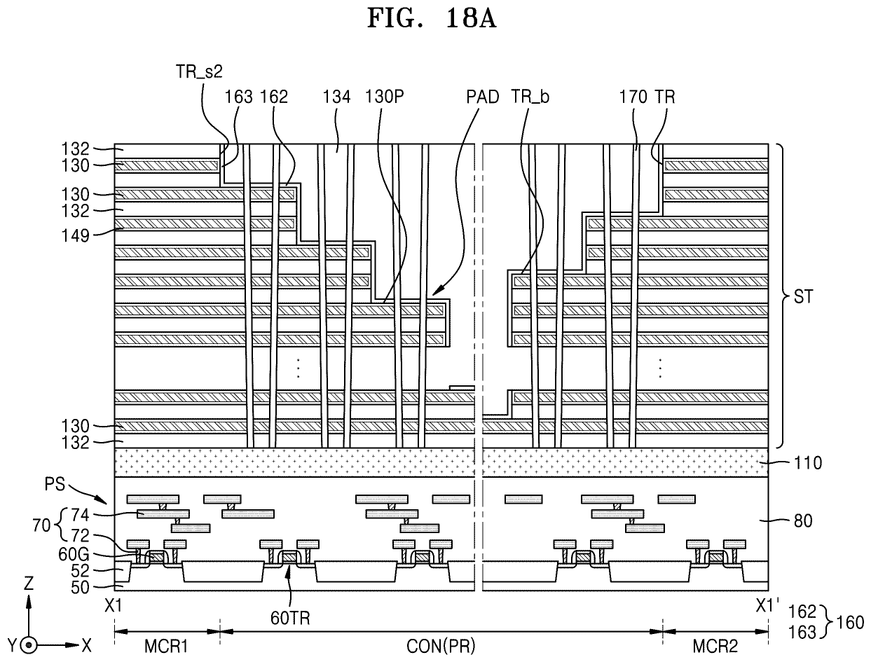

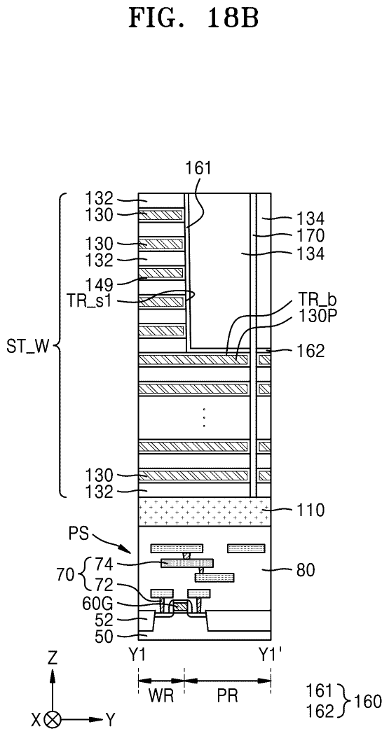

Referring to FIGS. 18A and 18B, the sacrificial layers S130 may be removed, and the dielectric liner 149 may be conformally formed on the top and bottom surfaces of each of the mold insulating layers 132. Subsequently, a gate electrode 130 may be formed by applying a conductive material to the dielectric liner 149.

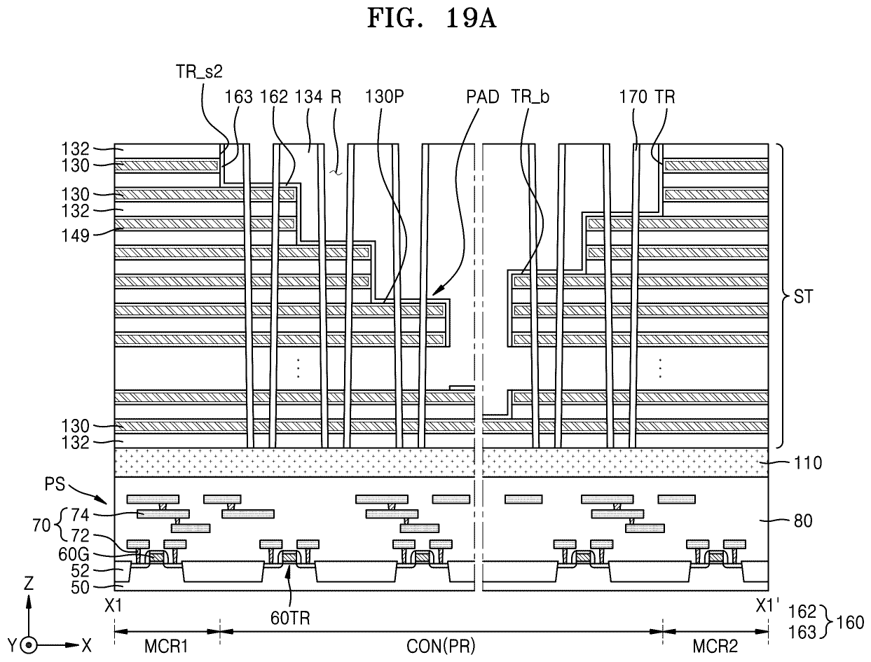

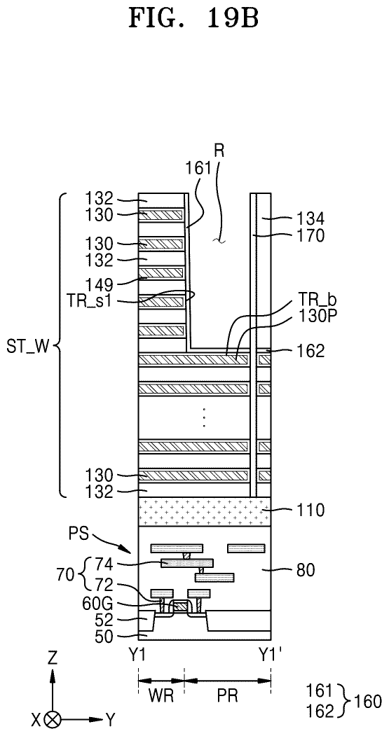

Referring to FIGS. 19A and 19B, the cover insulating layer 134, which is surrounded by the liner film 160 and the dam structure 170, may be partially etched. The cover insulating layer 134 may be partially etched by using a wet etching process. In detail, the cover insulating layer 134, which is surrounded by the liner film 160 and the dam structure 170, may be partially etched using an etchant. As described above, the cover insulating layer 134 may include a material that has a different etch selectivity with respect to the liner film 160 and the dam structure 170. In detail, the cover insulating layer 134 may include a material that has a high etch selectivity with respect to the liner film 160 and the dam structure 170. For example, the cover insulating layer 134 may include a material that has an etch selectivity of about 100 or more times with respect to the liner film 160 and the dam structure 170. Accordingly, while the cover insulating layer 134 is being removed by a wet etching process using an etchant, the liner film 160 and the dam structure 170 may not be removed.

Through the process described above, a plurality of recesses R, each surrounded by the liner film 160 and the dam structure 170, may be formed. Each of the recesses R may include a sidewall and a bottom surface, which are surrounded by the liner film 160 and the dam structure 170. The first part 161 of the liner film 160 and the inner wall of the dam structure 170 may be exposed by the sidewall of each of the recesses R. The second part 162 of the liner film 160 may be exposed by the bottom surface of each of the recesses R.

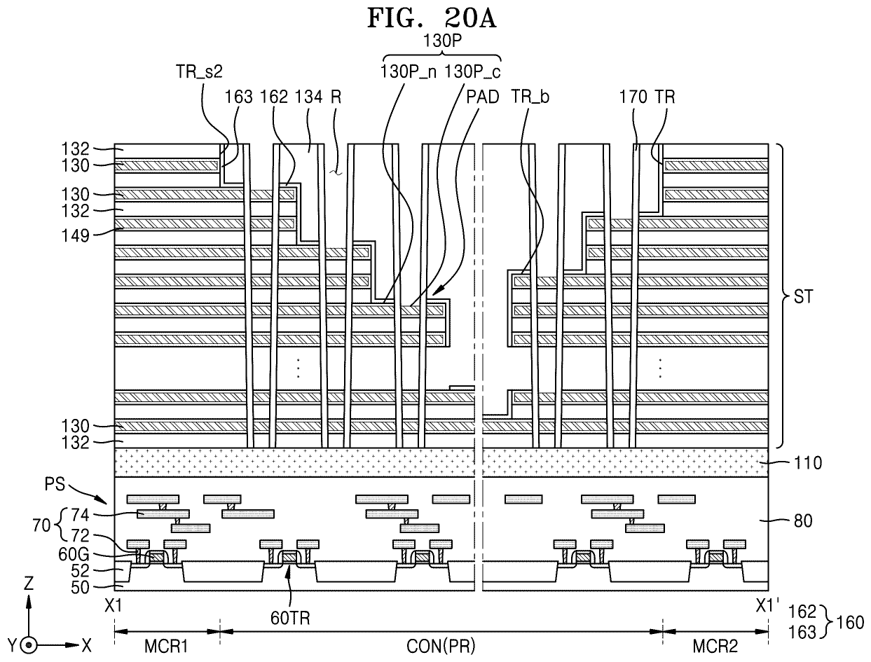

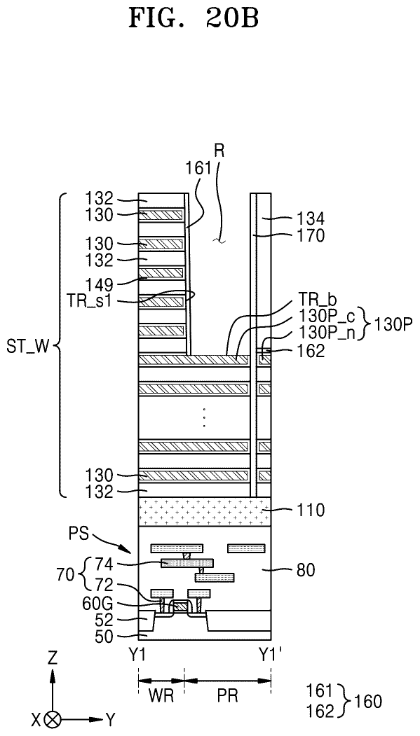

Referring to FIGS. 20A and 20B, the second part 162 of the liner film 160, which is exposed by each of the recesses R. In detail, a portion of the second part 162 of the liner film 160, which is exposed by the bottom surface of each recess R, may be removed. In some implementations, when the dielectric liner 149 is between the gate electrode 130 and one of the mold insulating layer 132, a portion of the dielectric liner 149 below the bottom surface of the recess R may also be removed. Through the process described above, the pad portion 130P of the gate electrode 130 may be exposed. In detail, a portion of the pad portion 130P of the gate electrode 130 may be exposed by the bottom surface of the recess R. The exposed portion of the pad portion 130P may be referred to as a connected portion 130P_c.

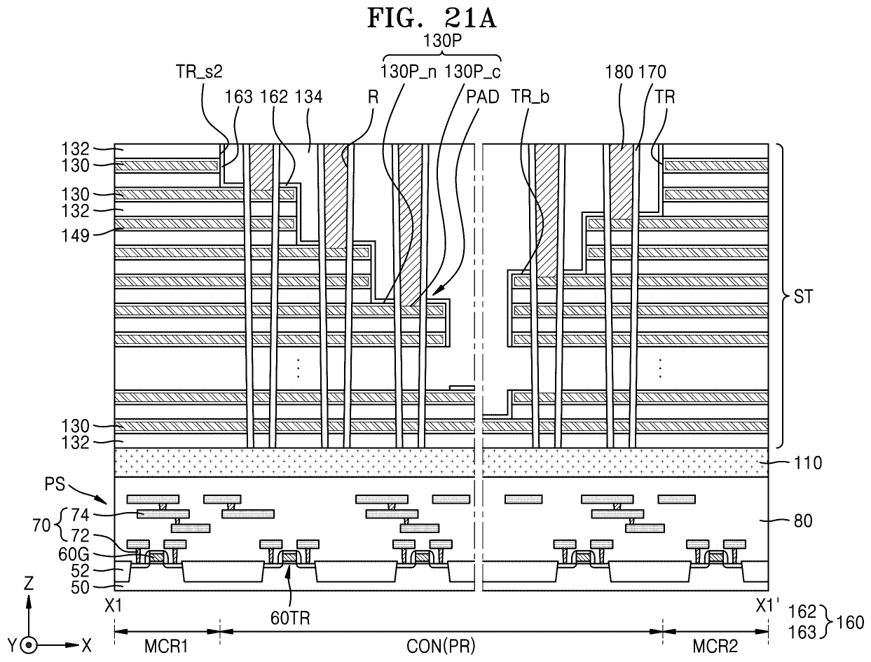

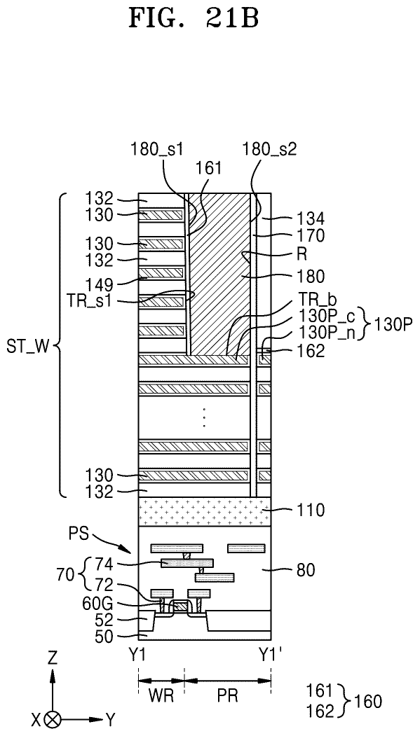

Referring to FIGS. 21A and 21B, a cell contact 180 may be formed to fill the recess R. In detail, the cell contact 180 may be formed to fill the recess R with a conductive material. The cell contact 180 may be connected to the pad portion 130P on the bottom surface of the recess R. In detail, the cell contact 180 may be connected to the connected portion 130P_c of the pad portion 130P on the bottom surface of the recess R.

Thereafter, subsequent processes may be performed on the resultant structure of FIGS. 21A and 21B to manufacture the non-volatile memory device 100 described with reference to FIGS. 3 to 8.

In some implementations, when the non-volatile memory device 100 is manufactured using the liner film 160 and the cover insulating layer 134, which have a different etch selectivity with respect to each other, the difficulty in manufacturing processes of the non-volatile memory device 100 may be reduced. In some implementations, when the non-volatile memory device 100 is manufactured using the dam structure 170 and the cover insulating layer 134, which have a different etch selectivity with respect to each other, the difficulty in manufacturing processes of the non-volatile memory device 100 may be reduced. In other words, the non-volatile memory device 100 with reduced process difficulty may be provided. In other words, an electronic system including the non-volatile memory device 100 with reduced process difficulty may be provided.

In some implementations, when the non-volatile memory device 100 is manufactured using the liner film 160 and the cover insulating layer 134, which have a different etch selectivity with respect to each other, failure of the non-volatile memory device 100 may be reduced and the performance of the non-volatile memory device 100 may be increased. In some implementations, when the non-volatile memory device 100 is manufactured using the dam structure 170 and the cover insulating layer 134, which have a different etch selectivity with respect to each other, failure of the non-volatile memory device 100 may be reduced and the performance of the non-volatile memory device 100 may be increased. In other words, the non-volatile memory device 100 having increased performance and reliability may be provided. In other words, an electronic system including the non-volatile memory device 100 having increased performance and reliability may be provided.

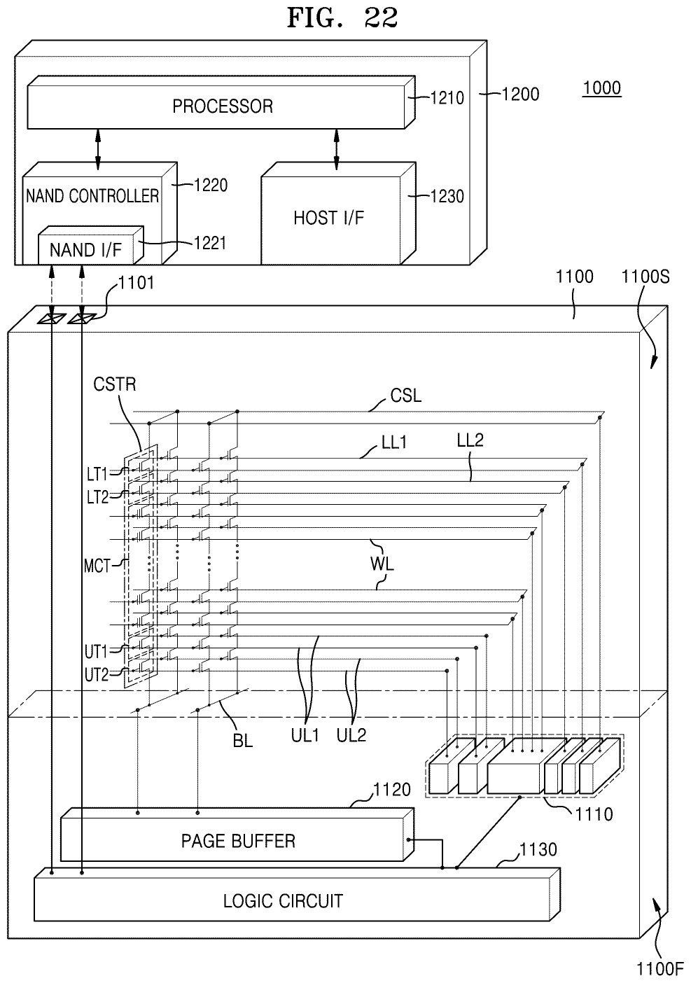

FIG. 22 is a schematic diagram of an example of a data storage system 1000 including a non-volatile memory device.

Referring to FIG. 22, the data storage system 1000 may include at least one non-volatile memory device 1100 and a memory controller 1200 electrically connected to the non-volatile memory device 1100. For example, the data storage system 1000 may correspond to any one of a solid state drive (SSD) device, a universal serial bus (USB) device, a computing system, a medical device, and a communication device, each of which includes the non-volatile memory device 1100.

For example, the non-volatile memory device 1100 may be a NAND flash non-volatile memory device including one of the non-volatile memory devices 100, 100A, 100B, 100C, 101, 102, 103, and 104 described with reference to FIGS. 1 to 13. The non-volatile memory device 1100 may include a first structure 1100F and a second structure 1100S on the first structure 1100F. The first structure 1100F may correspond to a peripheral circuit structure, which includes a row decoder 1110, a page buffer 1120, and a logic circuit 1130.

The second structure 1100S may correspond to a memory cell structure, which includes a bit line BL, a common source line CSL, a plurality of word lines WL, first and second string select lines UL1 and UL2, first and second ground select lines LL1 and LL2, and a plurality of memory cell strings CSTR between the bit line BL and the common source line CSL.

In the second structure 1100S, each of the memory cell strings CSTR may include ground select transistors LT1 and LT2 near the common source line CSL, string select transistors UT1 and UT2 near the bit line BL, and a plurality of memory cell transistors MCT between the ground select transistors LT1 and LT2 and the string select transistors UT1 and UT2. The number of ground select transistors LT1 and LT2 and the number of string select transistors UT1 and UT2 may vary with implementations.

In some implementations, the first and second ground select lines LL1 and LL2 may be respectively connected to the gate electrodes of the ground select transistors LT1 and LT2. The word lines WL may be respectively connected to the gate electrodes of the memory cell transistors MCT. The first and second string select lines UL1 and UL2 may be respectively connected to the gate electrodes of the string select transistors UT1 and UT2.

The common source line CSL, the first and second ground select lines LL1 and LL2, the word lines WL, and the first and second string select lines UL1 and UL2 may be connected to the row decoder 1110. A plurality of bit lines BL may be electrically connected to the page buffer 1120.

The non-volatile memory device 1100 may communicate with the memory controller 1200 through an I/O pad 1101, which is electrically connected to the logic circuit 1130. The I/O pad 1101 may be electrically connected to the logic circuit 1130.

The memory controller 1200 may include a processor 1210, a NAND controller 1220, and a host interface 1230. In some implementations, the data storage system 1000 may include a plurality of non-volatile memory devices 1100. In this case, the memory controller 1200 may control the plurality of non-volatile memory devices 1100.

The processor 1210 may generally control the operations of the data storage system 1000 including the memory controller 1200. The processor 1210 may operate according to certain firmware and may control the NAND controller 1220 to access the non-volatile memory device 1100. The NAND controller 1220 may include a NAND interface 1221 communicating with the non-volatile memory device 1100. A control command for controlling the non-volatile memory device 1100, data to be written to the memory cell transistors MCT of the non-volatile memory device 1100, data read from the memory cell transistors MCT of the non-volatile memory device 1100, and/or the like may be transmitted through the NAND interface 1221. The host interface 1230 may provide a function for communication between the non-volatile memory device 1100 and an external host. When receiving a control command from an external host through the host interface 1230, the processor 1210 may control the non-volatile memory device 1100 in response to the control command.

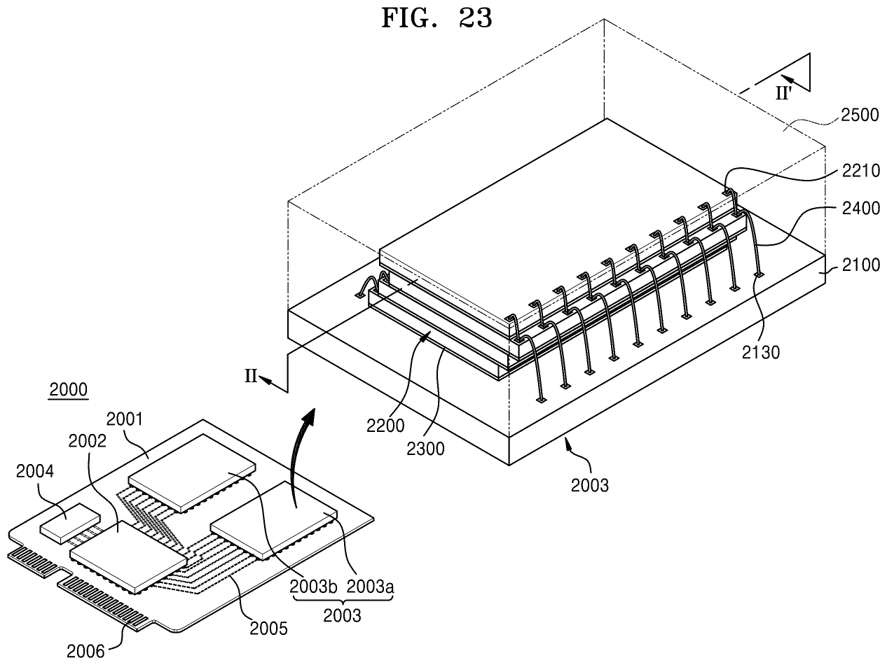

FIG. 23 is a schematic perspective view of an example of a data storage system 2000 including a non-volatile memory device.

Referring to FIG. 23, the data storage system 2000 may include a main board 2001, a memory controller 2002 mounted on the main board 2001, at least one semiconductor package 2003, and dynamic random access memory (DRAM) 2004. The semiconductor package 2003 and the DRAM 2004 may be connected to the memory controller 2002 by a plurality of wiring patterns 2005 formed on the main board 2001.

The main board 2001 may include a connector 2006, which includes a plurality of pins coupled to an external host. The number and placement of pins in the connector 2006 may vary with a communication interface between the data storage system 2000 and the external host. In some implementations, the data storage system 2000 may communicate with an external host according to any one of interfaces, such as USB, peripheral component interconnect express (PCI-Express), serial advanced technology attachment (SATA), and M-PHY for universal flash storage (UFS). In some implementations, the data storage system 2000 may be driven by electric power supplied from an external host through the connector 2006. The data storage system 2000 may further include a power management integrated circuit (PMIC), which distributes electric power supplied from the external host to the memory controller 2002 and the semiconductor package 2003.

The memory controller 2002 may write data to or read data from the semiconductor package 2003 and may increase the operating speed of the data storage system 2000.

The DRAM 2004 may function as a buffer memory for mitigating the speed difference between an external host and the semiconductor package 2003 that is a data storage space. The DRAM 2004 included in the data storage system 2000 may also operate as a sort of cache memory and provide a space for temporarily storing data in a control operation on the semiconductor package 2003. When the DRAM 2004 is included in the data storage system 2000, the memory controller 2002 may further include a DRAM controller for controlling the DRAM 2004 in addition to a NAND controller for controlling the semiconductor package 2003.

The semiconductor package 2003 may include first and second semiconductor packages 2003a and 2003b separated from each other. Each of the first and second semiconductor packages 2003a and 2003b may include a plurality of semiconductor chips 2200. Each of the first and second semiconductor packages 2003a and 2003b may include a package substrate 2100, the semiconductor chips 2200 on the package substrate 2100, an adhesive layer 2300 on the bottom surface of each of the semiconductor chips 2200, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may include a printed circuit board (PCB) including a plurality of package upper pads 2130. Each of the semiconductor chips 2200 may include an I/O pad 2210. The I/O pad 2210 may correspond to an I/O pad 1101 in FIG. 22. Each of the semiconductor chips 2200 may include at least one of the non-volatile memory devices 100, 100A, 100B, 100C, 101, 102, 103, and 104 described with reference to FIGS. 1 to 13.

In some implementations, the connection structure 2400 may include a bonding wire, which electrically connects the I/O pad 2210 to a package upper pad 2130. Accordingly, in the first and second semiconductor packages 2003a and 2003b, the semiconductor chips 2200 may be electrically connected to each other by a bonding wire and electrically connected to the package upper pads 2130 of the package substrate 2100. In some implementations, in the first and second semiconductor packages 2003a and 2003b, the semiconductor chips 2200 may be electrically connected to each other by a connection structure, which includes a through silicon via (TSV), instead of the connection structure 2400 using a bonding wire.

In some implementations, the memory controller 2002 and the semiconductor chips 2200 may be included in a single package. In some implementations, the memory controller 2002 and the semiconductor chips 2200 may be mounted on an interposer board separate from the main board 2001 and may be connected to each other by wiring formed on the interposer board.

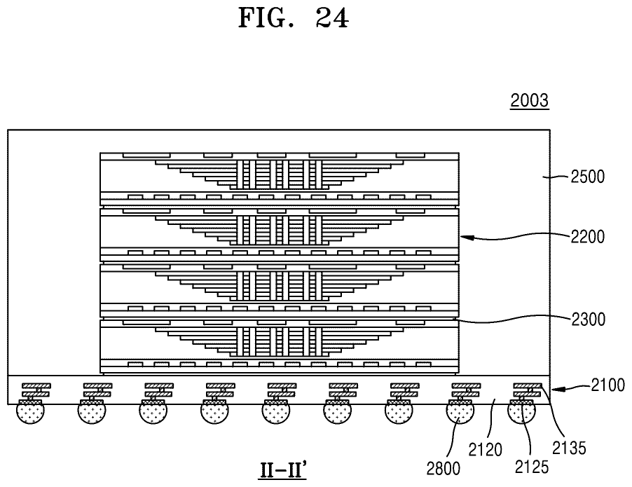

FIG. 24 is a schematic cross-sectional view of an example of a semiconductor package. In detail, FIG. 24 is a cross-sectional view taken along line II-II′ in FIG. 23.

Referring to FIG. 24, in the semiconductor package 2003, the package substrate 2100 may be a PCB. The package substrate 2100 may include a package substrate body 2120, a plurality of package upper pads (2130 in FIG. 23) on the top surface of the package substrate body 2120, a plurality of lower pads 2125 arranged on or exposed by the bottom surface of the package substrate body 2120, and a plurality of internal wires 2135, which are inside the package substrate body 2120 and electrically connect the package upper pads 2130 to the lower pads 2125. As shown in FIG. 23, the package upper pads 2130 may be electrically connected to a plurality of connection structures 2400. As shown in FIG. 24, the lower pads 2125 may be respectively connected to the wiring patterns 2005 on the main board 2001 of the data storage system 2000 of FIG. 23 through a plurality of conductive bumps 2800. Each of the semiconductor chips 2200 may include at least one of the non-volatile memory devices 100, 100A, 100B, 100C, 101, 102, 103, and 104 described with reference to FIGS. 1 to 13.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A non-volatile memory device comprising:
a substrate including a first cell region, a second cell region, and a connection region, the connection region being between the first cell region and the second cell region;
a mold structure including a plurality of gate electrodes and a plurality of mold insulating layers, the plurality of gate electrodes and the plurality of mold insulating layers being stacked on the substrate, the plurality of gate electrodes being stacked in a stepped pattern on a pad region of the connection region, and the plurality of mold insulating layers being alternately stacked with the plurality of gate electrodes;
a channel structure on the first cell region and the second cell region, the channel structure extending through the mold structure and crossing the plurality of gate electrodes;
a trench along a profile of the mold structure on the pad region of the connection region, the trench including a bottom surface and a first sidewall, the bottom surface having a stair shape, the first sidewall being on a boundary between the pad region of the connection region and a wall region of the connection region;
a liner film on the first sidewall of the trench;
a recess in the trench, the recess exposing a pad portion of a gate electrode among the plurality of gate electrodes and the liner film on the first sidewall of the trench;
a cell contact provided at the recess, the cell contact being connected with the pad portion of the gate electrode; and
a cover insulating layer provided at the trench,
wherein the liner film has a different etch selectivity than the cover insulating layer.

2. The non-volatile memory device of claim 1, wherein the cell contact includes a first sidewall on the liner film, the first sidewall of the cell contact being in contact with the liner film.

3. The non-volatile memory device of claim 1, wherein
the cell contact includes a second sidewall, the second sidewall being surrounded by a dam structure, and
the dam structure is between the cover insulating layer and the cell contact.

4. The non-volatile memory device of claim 3, wherein the second sidewall of the cell contact is in contact with the dam structure.

5. The non-volatile memory device of claim 3, wherein the dam structure has a different etch selectivity than the cover insulating layer.

6. The non-volatile memory device of claim 5, wherein the dam structure and the liner film include a same material.

7. The non-volatile memory device of claim 1, wherein
the mold structure includes a wall structure on the wall region,
the first sidewall of the trench exposes a portion of a sidewall of the wall structure, and
the liner film is in contact with the portion of the sidewall of the wall structure.

8. The non-volatile memory device of claim 1, wherein
the first cell region and the second cell region are spaced apart from each other in a first horizontal direction, and
the pad region and the wall region are positioned in a second horizontal direction on the connection region, the second horizontal direction crossing the first horizontal direction.

9. A non-volatile memory device comprising:
a peripheral circuit substrate;
a peripheral circuit device on the peripheral circuit substrate;
a cell substrate on the peripheral circuit substrate, the cell substrate including a first cell region, a second cell region, and a connection region, the second cell region being spaced apart from the first cell region in a first horizontal direction, the connection region being between the first cell region and the second cell region, the connection region including a pad region and a wall region, the pad region and the wall region being positioned in a second horizontal direction that crosses the first horizontal direction;
a mold structure including a plurality of gate electrodes and a plurality of mold insulating layers, the plurality of gate electrodes being stacked in a stepped pattern on the pad region of the connection region, the plurality of mold insulating layers being alternately stacked with the plurality of gate electrodes, and the mold structure including a wall structure on the wall region of the connection region;
a channel structure on the first cell region and the second cell region, the channel structure extending through the mold structure and crossing the plurality of gate electrodes;
a cell contact on the pad region of the connection region, the cell contact including a first sidewall on a sidewall of the wall structure, the cell contact being connected with a pad portion of a gate electrode among the plurality of gate electrodes;
a liner film on the first sidewall of the cell contact, the liner film including a first part extending in the first horizontal direction;
a cover insulating layer on the pad region, the cover insulating layer surrounding a second sidewall of the cell contact, the second sidewall of the cell contact opposite to the first sidewall of the cell contact; and
a dam structure between the second sidewall of the cell contact and the cover insulating layer,
wherein the liner film is in contact with the first sidewall of the cell contact, and
wherein the dam structure has a different etch selectivity than the cover insulating layer.

10. The non-volatile memory device of claim 9, wherein, in a plan view, the second sidewall of the cell contact is concave with respect to the first sidewall of the cell contact.

11. The non-volatile memory device of claim 10, wherein
in a plan view, the cell contact has a bow shape, and
the first sidewall and a second side wall of the cell contact define the bow shape.

12. The non-volatile memory device of claim 9, wherein the liner film has a different etch selectivity than the cover insulating layer.

13. The non-volatile memory device of claim 12, wherein the dam structure and the liner film include a same material.

14. The non-volatile memory device of claim 9, wherein
the pad portion of the gate electrode includes a connected portion and a non-connected portion, the connected portion being in contact with the cell contact, and the non-connected portion being not in contact with the cell contact, and
the cover insulating layer is positioned on the non-connected portion of the pad portion.

15. The non-volatile memory device of claim 14, wherein the liner film includes a second part, the second part being between the cover insulating layer and the non-connected portion of the pad portion of the gate electrode.

16. The non-volatile memory device of claim 15, wherein a vertical level of the second part of the liner film has a stair shape in the first horizontal direction.

17. An electronic system comprising:
a main substrate;
a non-volatile memory device on the main substrate; and
a controller on the main substrate, the controller being electrically connected with the non-volatile memory device,
wherein the non-volatile memory device includes:
a cell substrate including a first cell region, a second cell region, and a connection region, the connection region being between the first cell region and the second cell region;
a mold structure including a plurality of gate electrodes and a plurality of mold insulating layers, the plurality of gate electrodes and the plurality of mold insulating layers being stacked on the cell substrate, the plurality of gate electrodes being stacked in a stepped pattern on a pad region of the connection region, and the plurality of mold insulating layers being alternately stacked with the plurality of gate electrodes;
a channel structure on the first cell region and the second cell region, the channel structure extending through the mold structure and crossing the plurality of gate electrodes;
a cell contact on the pad region of the connection region, the cell contact including a bottom surface and a first sidewall, the first sidewall being on a boundary between the pad region of the connection region and a wall region of the connection region, the bottom surface being connected with a pad portion of a gate electrode among the plurality of gate electrodes;
a liner film including a first part, the first part positioned on the first sidewall of the cell contact;
a cover insulating layer on the pad region of the connection region, the cover insulating layer surrounding a second sidewall of the cell contact, the second sidewall of the cell contact being opposite to the first sidewall of the cell contact; and
a dam structure between the second sidewall of the cell contact and the cover insulating layer,
wherein the liner film is in contact with the first sidewall of the cell contact, and
wherein the liner film has a different etch selectivity than the cover insulating layer.

18. The electronic system of claim 17, wherein the dam structure has a different etch selectivity than the cover insulating layer.

19. The electronic system of claim 17, wherein, in a plan view, the second sidewall of the cell contact is concave with respect to the first sidewall of the cell contact.

20. The electronic system of claim 19, wherein
in a plan view, the cell contact has a semicircular shape, and
the first sidewall and a second side wall of the cell contact define the semicircular shape.
